(19) United States
(12) Patent Application Publication
(10) Pub. No.: US 2024/0404974 A1
(43) Pub. Date: Dec. 5, 2024

(54) PANEL-LEVEL SEMICONDUCTOR PACKAGING METHOD

(71) Applicant: PEP INNOVATION PTE. LTD., Singapore (SG)

(72) Inventors: Munirathinam Senthil Kumar, Singapore (SG); Hwee Seng Chew, Singapore (SG)

(21) Appl. No.: 18/677,922

(22) Filed: May 30, 2024

(30) Foreign Application Priority Data
May 31, 2023 (SG) 10202301536S
Jun. 3, 2023 (SG) 10202301563T

(51) Int. Cl. H01L 23/00; G06F 30/392; H01L 21/56; H01L 21/66; H01L 21/68; H01L 21/78

(52) U.S. Cl. CPC H01L 24/19; G06F 30/392; H01L 21/561; H01L 21/68; H01L 22/12; H01L 24/97; H01L 21/78; H01L 24/83; H01L 2224/19; H01L 2224/83052; H01L 2224/95136

(57) ABSTRACT

A method is disclosed for forming a circuit layer on diverse semiconductor devices, including semiconductor dies and passive packages, within an electronic module. The method comprises generating a Die Location Check (DLC) file to store true positions of the semiconductor devices on a reconstructed panel, Next, a green circuit file specifying the intended positions for the semiconductor devices on the circuit layer is retrieved. Using the DLC file, these intended positions are then adjusted to match the true positions, resulting in an adapted circuit file. Finally, this adapted file guides the formation of the circuit layer, ensuring it aligns precisely with the semiconductor devices. The present application also discloses a method of generating a DLC file for determining true positions of a plurality of semiconductor devices in a reconstructed panel. The present application further discloses a panel-level semiconductor packaging method for making a plurality of electronic modules.

### CROSS-REFERENCE TO RELATED APPLICATIONS

This application claims the benefit of Singapore Provisional Applications No. 10202301536S filed on May 31, 2023 and No. 10202301563T filed on Jun. 3, 2023, the disclosures of which are herein incorporated by reference in their entireties for all purposes.

### TECHNICAL FIELD

The present application relates to a panel-level semiconductor packaging method for making electronic modules. The present application also relates to a method of forming a circuit layer of the electronic modules. The present application further relates to a method of generating a die location check (DLC) file for detecting true positions of semiconductor dies in a reconstructed panel in the panel-level semiconductor packaging method.

### BACKGROUND

Current panel-level semiconductor packaging methods face a serious challenge that semiconductor dies would shift away from their green or as-designed positions in a reconstituted panel. The shift may be caused during multiple processes, such as bonding the semiconductor dies onto a panel, and forming a molding layer for encapsulating the semiconductor dies on the panel. The shift would make it difficult for subsequent processes, such as forming a circuit layer on the reconstituted panel.

Therefore, the present application discloses a panel-level semiconductor packaging method for resolving the problem in the subsequent processes caused by the shift of the semiconductor dies in the reconstituted panel.

### SUMMARY

As a first aspect, the present application discloses a method of forming a circuit layer on a plurality of semiconductor devices which include semiconductor dies and passive packages for an electronic module. The method includes generating a die location check (DLC) file which comprises true positions of the semiconductor devices in a reconstructed panel; retrieving a green circuit file having green positions for the semiconductor devices; transforming the green circuit file to an adapted circuit file by the DLC file, wherein the green positions are aligned to the true positions for the semiconductor devices; and forming the circuit layer on the semiconductor devices at the true positions according to the adapted circuit file.

As a second aspect, the present application discloses a method of generating a die location check (DLC) file for determining true positions of a plurality of semiconductor devices in a reconstructed panel. The method includes conducting a post-bonding inspection for inspecting the semiconductor devices bonded on a marked carrier before forming the reconstructed panel; forming a molding layer for encapsulating the semiconductor devices mounted on the marked carrier for forming the reconstructed panel; and scanning the semiconductor devices in the reconstructed panel for detecting true positions of the semiconductor devices in the reconstructed panel.

As a third aspect, the present application discloses a panel-level semiconductor packaging method for making a plurality of electronic modules. The method includes providing a marked carrier; aligning and bonding a plurality of semiconductor devices onto the marked carrier; forming a molding layer for forming a reconstructed panel; releasing the reconstructed panel from the marked carrier and then transferring the reconstructed panel to a carrier plate; performing the method for forming a circuit layer on the semiconductor devices molded in the reconstructed panel; forming an external connection layer on circuit layer; and singulating the reconstructed panel and the external connection layer into the individual electronic modules.

### BRIEF DESCRIPTION OF THE DRAWINGS

The accompanying figures (Figs.) illustrate embodiments and serve to explain principles of the disclosed embodiments. It is to be understood, however, that these figures are presented for purposes of illustration only, and not for defining limits of relevant applications.

FIG. 1 illustrates a flow chart of a method S10 of making passive packages including passive components according to an exemplary embodiment of the present disclosure;

FIGS. 2a to 2h illustrate schematic diagrams of processing steps of the method S10;

FIGS. 2i and 2j illustrate schematic diagrams of the passive packages;

FIG. 3 illustrates a flow chart of a panel-level semiconductor packaging method S20 for semiconductor devices, according to an exemplary embodiment of the present disclosure;

FIGS. 4a to 4e illustrate schematic diagrams of S21 of providing a marked carrier for multiple chip module (MCM);

FIG. 5 illustrates a schematic diagram of S21 of providing another marked carrier for single chip module (SCM);

FIG. 6a illustrates a schematic diagram of S22 matching a die pattern from a computer-aided design (CAD) die pattern for a semiconductor die;

FIG. 6b illustrates a schematic diagram of S22 of matching a unit pattern from a computer-aided design (CAD) unit pattern for the marked carrier in FIG. 4a;

FIGS. 7a to 7c illustrate schematic diagrams of S23 of aligning and bonding the semiconductor die to a bonding region on the marked carrier;

FIGS. 8a and 8b illustrate schematic diagrams of S23 of aligning and bonding the multiple semiconductor dies to a bonding unit on the marked carrier for MCM in FIG. 4a;

FIGS. 9a and 9b illustrate schematic diagrams of embodiments of a vision apparatus for the alignment and the bonding in FIG. 7 and FIG. 8;

FIGS. 10a and 10b illustrate schematic diagrams of a post-bonding inspection to the semiconductor die bonded in the bonding region on the marked carrier;

FIGS. 11a and 11b illustrate schematic diagrams of the semiconductor dies bonded on the marked carrier for the MCM;

FIGS. 12a and 12b illustrate schematic diagrams of S24 of forming a molding layer for encapsulating the semiconductor dies to form a reconstructed panel;

FIGS. 13a and 13b illustrate schematic diagrams of a first sub-step of S25 of releasing the reconstructed panel from the marked carrier;

FIGS. 14a and 14b illustrate schematic diagrams of a second sub-step of S25 of transferring the reconstructed panel to a carrier plate, and then S26 of performing a die location check (DLC) process for generating a DLC file;

FIGS. 15a and 15b illustrate schematic diagrams of a first sub-step S271 of S27 of forming a thin metal layer on an active side of the reconstructed panel;

FIG. 16 illustrates a schematic diagram of a second sub-step S272 of S27 of forming a first dry film layer on the thin metal layer and the active side of the reconstructed panel;

FIG. 17 illustrates a schematic diagram of a third sub-step S273 of S27 of forming a first patterned dry film layer to the first dry film layer;

FIG. 18 illustrates a schematic diagram of a fourth sub-step S274 of S27 of forming a trace layer based on the first patterned dry film layer;

FIG. 19 illustrates a schematic diagram of a fifth sub-step S275 of S27 of forming a second dry film layer on the first patterned dry film layer and the trace layer;

FIG. 20 illustrates a schematic diagram of a sixth sub-step S276 of S27 of forming a second patterned dry film layer to the second dry film layer;

FIG. 21 illustrates a schematic diagram of a seventh sub-step S277 of S27 of forming a stud layer based on the second patterned dry film layer;

FIG. 22 illustrates a schematic diagram of an eighth sub-step S278 of S27 of removing the first patterned dry film and the second patterned dry film;

FIG. 23 illustrates a schematic diagram of a ninth sub-step S279 of S27 of forming a dielectric layer onto the trace layer and the stud layer;

FIG. 24 illustrates a schematic diagram of removing a top portion of the dielectric layer for exposing the stud layer;

FIG. 25 illustrates a schematic diagram of S28 of forming solder balls on the stud layer;

FIGS. 26a and 26b illustrate schematic diagrams of S29 of separating the reconstructed panel into individual semiconductor packages (MCMs);

FIGS. 27a to 27e illustrate schematic diagrams of a method of transforming a green circuit file to an adapted circuit file (including a trace file and a stud file) according to the DLC file;

FIG. 28 illustrates schematic diagrams of different scenarios of the DLC file, the trace file and the stud file of the adapted circuit file according to the method in FIGS. 27a to 27e;

FIGS. 29a to 29d illustrate schematic diagrams of another method of transforming the green circuit file to the adapted circuit file (including a trace file and a stud file) according to the DLC file;

FIG. 30 illustrates schematic diagrams of different scenarios of the DLC file, the trace file and the stud file of the adapted circuit file according to the method in FIGS. 29a to 29d;

FIG. 31 illustrates a schematic diagram of a block of the semiconductor packages (MCMs);

FIG. 32 illustrate a schematic diagram of a panel of the blocks and sub-blocks of the semiconductor packages (MCMs).

### DETAILED DESCRIPTION OF THE INVENTION

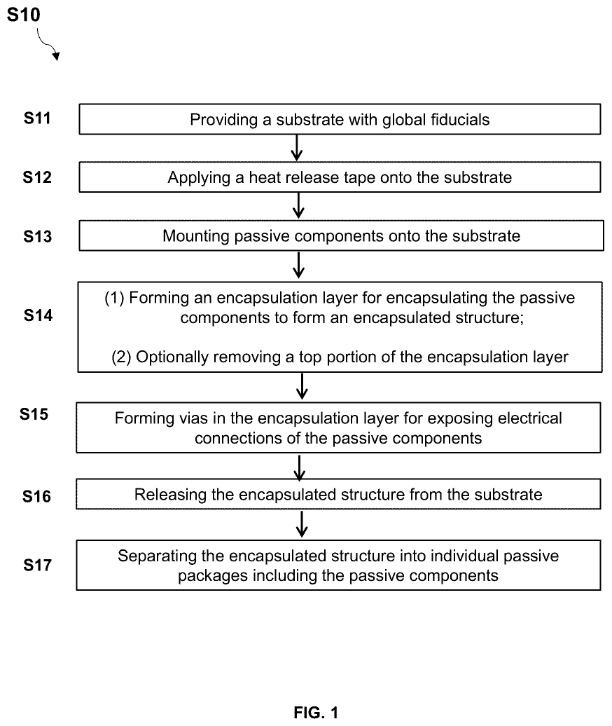

FIG. 1 illustrates a flow chart of a method S10 of making passive packages 110 including passive components 100 according to an exemplary embodiment of the present disclosure. The method S10 includes a Step S11 to a Step S17 as illustrated in the following.

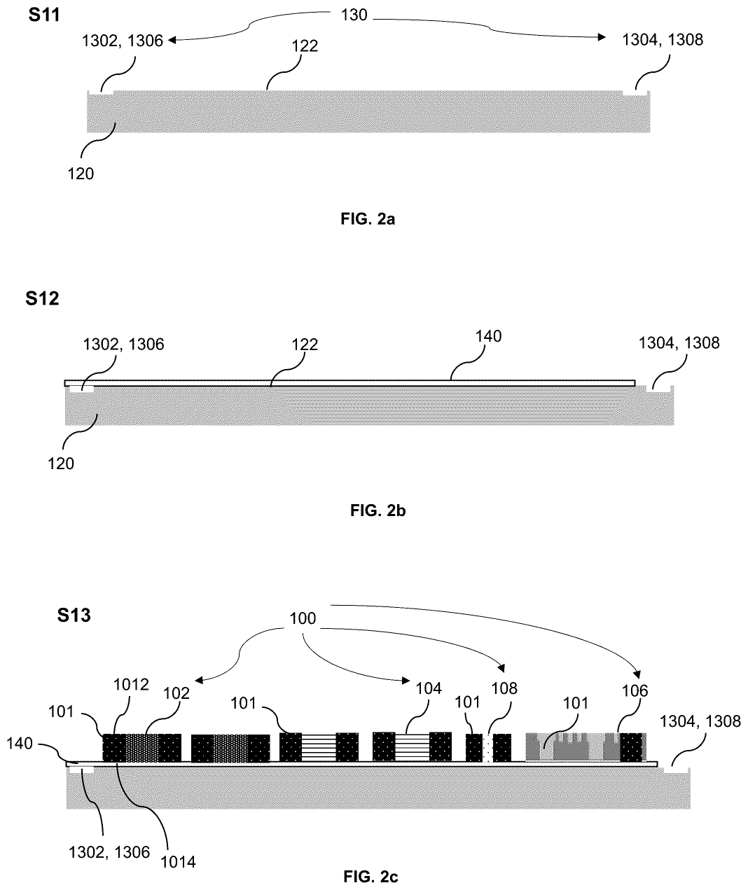

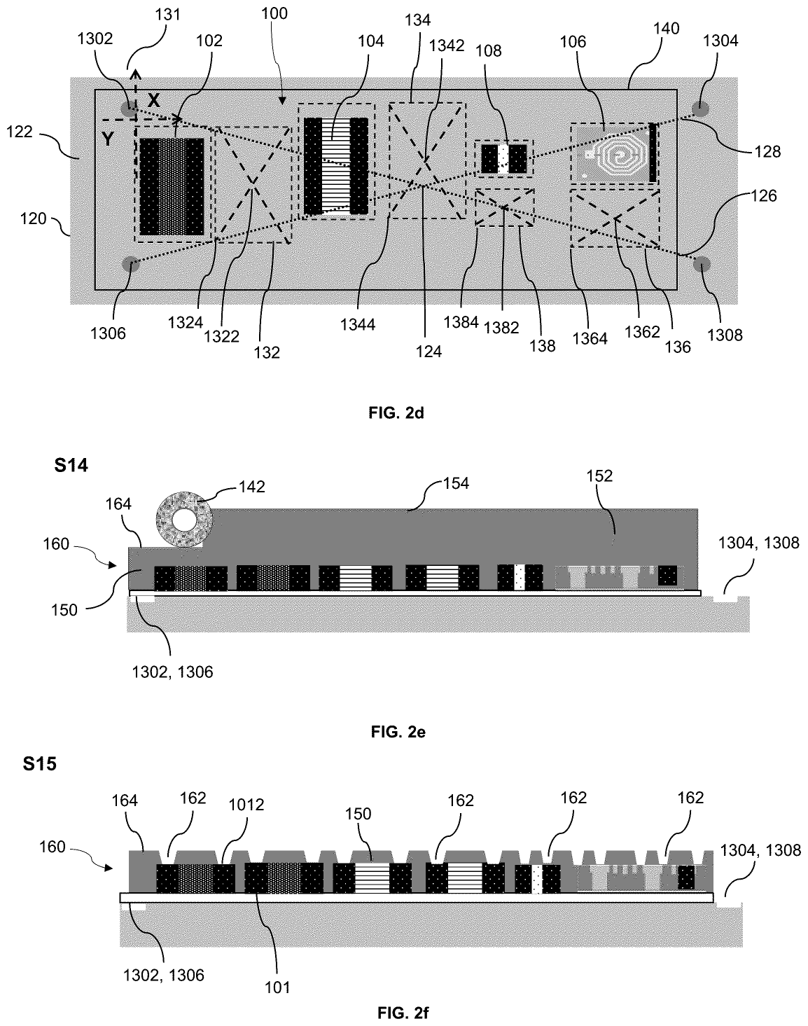

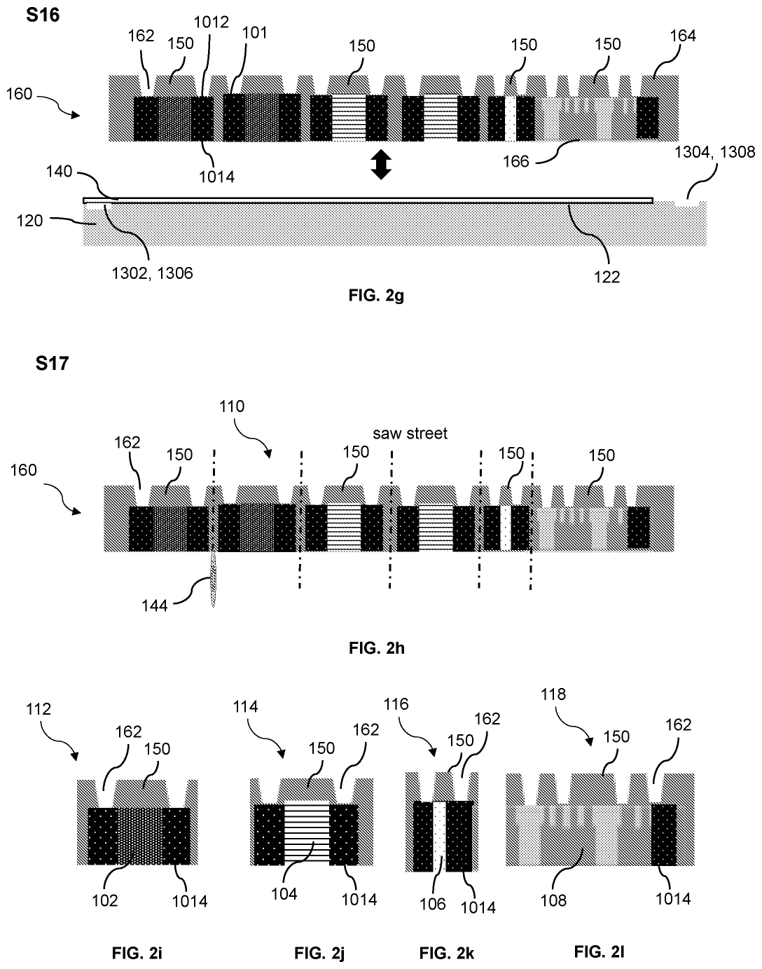

The method S10 includes the Step S11 of providing a substrate 120 with global fiducials 130. FIG. 2a shows a cross-sectional view of a portion of the substrate 120 which has a front surface 122. The global fiducials 130 are formed as shallow grooves on the front surface 122 for guiding the passive components 100 to be mounted at their pre-determined locations on the substrate 120. If the substrate 120 has a large dimension, multiple global fiducials 130 may be formed at peripheries of the front surface 122. In one embodiment, four global fiducials 130 are formed at four corners of the substrate 120 respectively, including a first global fiducial 1302 and a second global fiducial 1304 as shown in FIG. 2a, as well as a third global fiducial 1306 and a fourth global fiducial 1308 which are overlapped with the first global fiducial 1302 and the second global fiducial 1304 respectively in FIG. 2a. The global fiducials 130 may be made permanently on the front surface 122 by any known technologies, such as laser drilling, mechanical drilling, chemical etching, or their combination. The global fiducials 130 cannot be cased without removing the front surface 122 of the substrate 120. Alternatively, the global fiducials 130 may be made temporarily such as by painting or other similar known technologies, so that they can be erased while the front surface 122 is kept intact.

The method S10 includes the Step S12 of applying a heat release tape (also called thermal release tape) 140 onto the front surface 122 of the substrate 120. FIG. 2b shows a cross-sectional view of the heat release tape 140 covering the front surface 122. The heat release tape 140 on the one hand can be secured to the front surface 122 of the substrate 120; and on the other hand, can secure the passive components 100 mounted on the substrate 120. However, due to smaller sizes and lighter weights of the passive components 100, adhesion of the heat release tape 140 may not be strong enough for holding the passive components 100 firmly in place during subsequent processes. The heat release tape 140 may also cover the global fiducials 130, such as the first global fiducial 1302. Accordingly, the heat release tape 140 may be transparent or semi-transparent so that the first global fiducial 1302 could be seen or detected through the heat release tape 140. Alternatively, the heat release tape 140 may not cover the global fiducials 130, such as the second global fiducial 1304 and the fourth global fiducial 1308 as shown in FIG. 2b.

The method S10 includes the Step S13 of mounting the passive components 100 onto the heat release tape 140 and the front surface 122 of the substrate 120. The passive components 100 may include any passive components which do not have active electronic functions, such as capacitors 102, resistors 104, inductors 106 and Copper blocks 108. The passive components 100 have electrical connections 101 for coupling the passive components 100 electrically with each other or with active components such as semiconductor dies. FIG. 2c shows a cross-sectional view that the passive components 100 are mounted at their pre-determined locations on the front surface 122 of the substrate 120; and the pre-determined locations are decided on the front surface 122 according to the global fiducials 130. However, it may be not required to mount the passive components 100 very precisely at the pre-determined locations which would cost too much time and lead to lower processing efficiency. For example, the passive components 100 may be mounted by a high-speed chip shooter which would mount the passive components 100 in a rough but faster manner onto the substrate 120. FIG. 2c also shows that the electrical connections 101 have a bottom surface 1014 in contact with the heat release tape 140, and a front surface 1012 opposed to the bottom surface 1014. Both the bottom surface 1014 and the front surface 1012 are electrically conducting for coupling the passive components 100 electrically with each other or with active components.

FIG. 2d shows a top view of the passive components 100 mounted in a matrix of rows and columns on the front surface 122 of the substrate 120. A substrate coordinate system 131 is established on the front surface 122 of the substrate 120 for deciding the pre-determined locations for mounting the passive components 100. The substrate coordinate system 131 may be any kinds of coordinate system that is suitable for the purpose of deciding the pre-determined locations for mounting the passive components 100. For example, the substrate coordinate system 131 may be a Cartesian coordinate system as illustrated in FIG. 2d. In the Cartesian coordinate system, the substrate coordinate system 131 may adopt any point on the front surface 122 of the substrate 120 as an origin (0, 0). In an embodiment, the substrate coordinate system 131 adopts one of the global fiducials 130 such as the first global fiducial 1302 as the origin (0, 0) for the Cartesian coordinate system. In another embodiment, the substrate coordinate system 131 adopts a substrate center 124 as the origin (0, 0). The substrate center 124 is determined as an intersectional point of a first diagonal line 126 and a second diagonal line 128, as indicated by dotted lines in FIG. 2d. The first diagonal line 126 is drawn between the first global fiducial 1302 and the fourth global fiducial 1308; while the second diagonal line 128 is drawn between the second global fiducial 1304 and third global fiducial 1306.

As shown in FIG. 2d, the pre-determined locations for the passive components 100 are indicated by dashed rectangles, such as a first dashed rectangle 132 for the pre-determined location of the capacitors 102, a second dashed rectangle 134 for the pre-determined location of the resistors 104, a third dashed rectangle 136 for the pre-determined location of the inductors 106, and a fourth dashed rectangle 138 for the pre-determined location of the Copper blocks 108. It is understood that the pre-determined location may be represented by a coordinate (x, y) of any point on or within the dashed rectangle in the substrate coordinate system 131. For example, the pre-determined locations of the capacitors 102, the resistors 104, the inductors 106 and the Copper blocks 108 can be represented by a first location center 1322, a second location center 1342, a third location center 1362 and a fourth location center 1382 of their respective dashed rectangles 132, 134, 136, 138. Alternatively, the pre-determined locations of the capacitors 102, the resistors 104, the inductors 106 and the Copper blocks 108 can be represented by a first location corner 1324, a second location corner 1344, a third location corner 1364 and a fourth location corner 1384 of their respective dashed rectangles 132, 134, 136, 138. The dashed rectangle may be slightly larger than the passive components 100; and it is only required that the passive components 100 are mounted within the dashed rectangles, regardless whether the passive components 100 are mounted precisely at the pre-determined locations in the dashed rectangles. For example, the capacitors 102, the resistors 104, the inductors 106, the Copper blocks 108 may be mounted symmetrically to the first location center 1322, the second location center 1342, the third location center 1362, the fourth location center 1382 of the dashed rectangles 132, 134, 136, 138 respectively. For another example, the capacitors 102, the resistors 104, the inductors 106, the Copper blocks 108 may be mounted at offset positions in the dashed rectangles 132, 134, 136, 138, where the offset positions are not overlapped with the first location center 1322, the second location center 1342, the third location center 1362, and the fourth location center 1382.

The method S10 includes the Step S14 of forming an encapsulation layer 150 for encapsulating the passive components 100 to form a molded structure 160. Then, the Step S14 optionally includes removing a top portion 152 of the encapsulation layer 150 from a top side 154 of the encapsulation layer 150, so that the molded structure 160 would have a thin profile. FIG. 2c shows a cross-sectional view that the top portion 152 is removed from the encapsulation layer 150 by a grinding wheel 142. The grinding may relieve internal stress generated in the encapsulation layer 150; and meanwhile form a front side 164 for the molded structure 160 which is ground to have a greater flatness than the top side 154 in order to perform subsequent processes such as the Step S15 better.

The method S10 includes the Step S15 of forming vias 162 in the encapsulation layer 150 from the front side 164 for exposing the front surface 1012 of the electrical connections 101 from the encapsulation layer 150. FIG. 2f shows a cross-sectional view that the vias 162 are formed for exposing the front surface 1012 of the electrical connections 101 for the capacitors 102, the resistors 104, the inductors 106 and the Copper blocks 108. As described above, the front side 164 of the molded structure 160 is rather flat so that the vias 162 can be formed more easily and efficiently.

The method S10 includes the Step S16 of releasing the molded structure 160 from the heat release tape 140 and the substrate 120. FIG. 2g shows a cross-sectional view that a bottom side 166, opposed to the front side 164 of the molded structure 160 is exposed from the heat release tape 140 and the substrate 120. Since the front surface 122 of the substrate 120 is rather flat, the bottom side 166 is also flat after being released from the substrate 120. Accordingly, the bottom surface 1014 of the electrical connections 101 is exposed from the heat release tape 140 and the substrate 120 after the release. Therefore, the passive components 100 may be electrically coupled with each other or with active electronic components such as semiconductor dies from either the front surface 1012 or the bottom surface 1014, or from both thereof.

The method S10 includes the Step S17 of separating the molded structure 160 into individual passive packages 110 including the passive components 100. The singulation may be conducted by sawing the molded structure 160 with a saw blade 144 along saw streets shown as dash-dotted lines in a cross-sectional view in FIG. 2h. After the singulation, the passive packages 110 are produced with larger sizes and heavier weights than the passive components 100; and thus the passive packages 110 could be adhered more firmly to a heat release tape 240 in subsequent process. As shown in FIGS. 2i to 2j, the passive packages 110 may be packaged capacitors 112 including the capacitors 102 (as shown in FIG. 2i), packaged resistors 114 including the resistors 104 (as shown in FIG. 2j), packaged inductors 116 including the inductors 106 (as shown in FIG. 2k), and packaged Copper blocks 118 including the Copper blocks 108 (as shown in FIG. 2j).

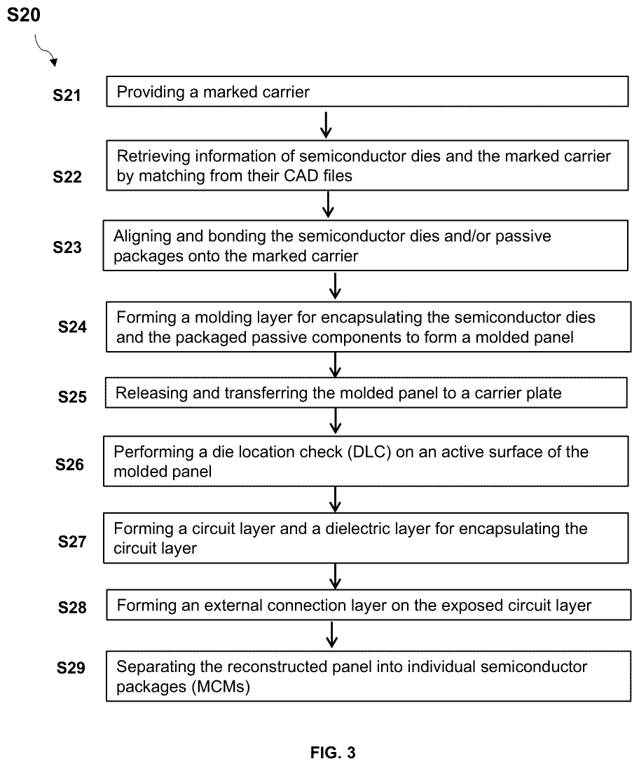

FIG. 3 illustrates a flow chart of a panel-level semiconductor packaging method S20 for semiconductor devices, according to an exemplary embodiment of the present disclosure. The semiconductor devices include semiconductor dies which have active electronic functions; and also the passive packages 110 as described above. The method S20 includes Step S21 to Step S29 as illustrated in the followings.

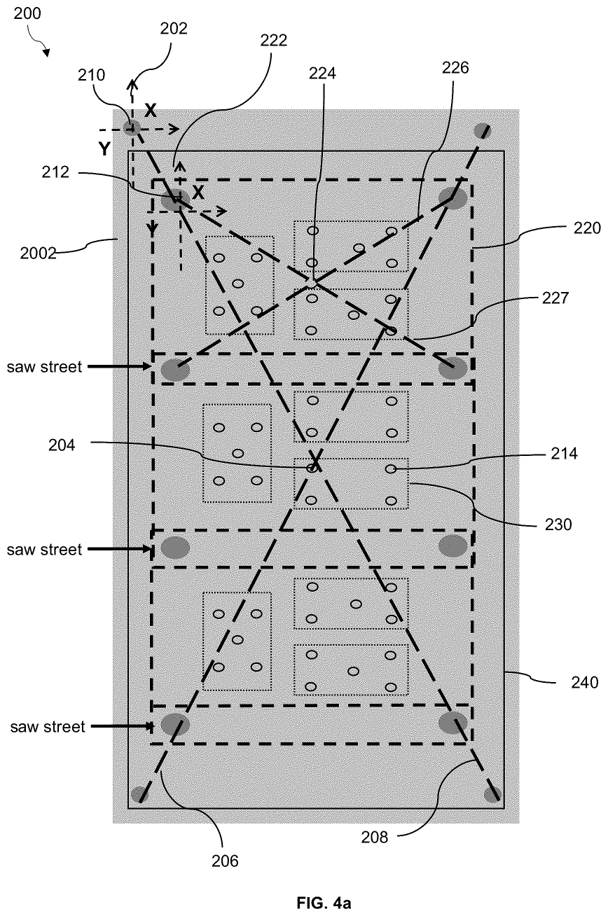

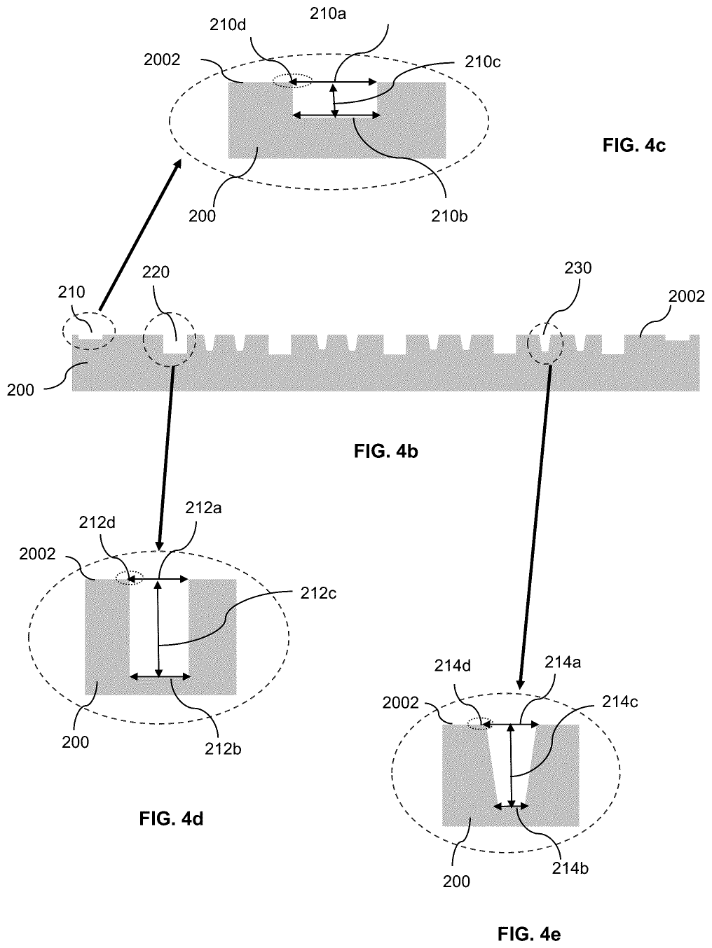

The method S20 includes the Step S21 of providing a marked carrier 200, 200a for making electronic modules, such as multiple chip modules (MCMs) or single chip modules (SCMs). FIG. 4 shows a top view of a portion of the marked carrier 200 with multiple bonding units 220 as indicated by dashed rectangles on a front surface 2002 of the marked carrier 200; and each bonding unit 220 may have multiple (such as 3 as shown in FIG. 4a) bonding regions 230 as indicated by dotted rectangles. Since each bonding region 230 could accommodate one semiconductor die, each bonding unit 220 may accommodate multiple semiconductor dies (such as 3 semiconductor dies shown in FIG. 4a) electrically coupled for fabricating MCMs. The MCMs are separated by a sawing process following saw streets as shown in FIG. 4a. Similarly to the substrate 120, multiple global fiducials 210 may be formed at peripheries of the marked carrier 200 for determining locations of the bonding units 220 on the front surface 2002 of the marked carrier 200. While multiple local fiducials 212 are formed at peripheries of the bonding unit 220 for determining locations of the bonding regions 230; and the bonding region 230 also has die markings 214 for precisely guiding the semiconductor dies to be bonded within the bonding region 230. Therefore, each of the semiconductor dies could be precisely bonded at its pre-determined location on the front surface 2002 of the marked carrier 200.

Similar to the substrate coordinate system 131 for the substrate 120, a carrier coordinate system 202 may be established for deciding the pre-determined locations for the bonding units 220; and a unit coordinate system 222 may also be similarly established for deciding the pre-determined locations for the bonding regions 230. The carrier coordinate system 202 and the unit coordinate system 222 may be any kinds of coordinate system that is suitable for their respective purposes. For example, the carrier coordinate system 202 and the unit coordinate system 222 may be Cartesian coordinate systems as illustrated in FIG. 4a. For the Cartesian coordinate system, the carrier coordinate system 202 and the unit coordinate system 222 may adopt any point on the front surface 2002 of the marked carrier 200 as an origin (0, 0). In an embodiment, the carrier coordinate system 202 and the unit coordinate system 222 adopt one of the global fiducials 210 and one of the local fiducials 212 as the origin (0, 0) for the Cartesian coordinate system respectively. In another embodiment, the carrier coordinate system 202 and the unit coordinate system 222 adopt a carrier center 204 and a unit center 224 as the origin (0, 0) of Cartesian coordinate system respectively. The carrier center 204 is determined as an intersectional point of a first carrier diagonal line 206 and a second carrier diagonal line 208 which are drawn between the global fiducials 210 diagonally, as indicated by the diagonal dashed lines in FIG. 4a. Similarly, the unit center 224 determined as an intersectional point of a first unit diagonal line 226 and a second unit diagonal line 227 which are drawn between the local fiducials 212 diagonally, as indicated by the diagonal dotted lines in FIG. 4a.

The global fiducials 210, the local fiducials 212 and the die markings 214 may be made permanently on the front surface 2002 of the marked carrier 200 as grooves by any known technologies, such as laser drilling, mechanical drilling, chemical etching, or their combination where they cannot be cased without removing the front surface 2002 of the marked carrier 200. FIG. 4b shows a cross-sectional view of the global fiducials 210, the local fiducials 212 and the die markings 214 according to an exemplary embodiment. Similar to the global fiducials 130, the global fiducials 210 are formed as shallow grooves; while the local fiducials 212 may be formed as cylindrical grooves, and the die markings 214 may be formed as truncated grooves. FIGS. 4c, 4d and 4e show enlarge cross-sectional views of the shallow groove of the global fiducials 210, the cylindrical groove of the local fiducials 212, and the truncated groove of the die markings 214. The global fiducials 210 and the local fiducials 212 have a rectangular shape in the cross-sectional views so that a top surface 210a, 212a equaling to a bottom surface 210b, 212b; while a depth 210c of the global fiducials 210 is smaller than a depth 212c of the local fiducials 212. In an embodiment, the top surface 212a and the bottom surface 212b have a circular shape with a diameter of around 0.15 millimeters (mm); while the depth 212c in a range of 0.02 to 0.06 millimeters (mm). While the die markings 214 has a trapezoid shape in the cross-sectional view with a top surface 214a larger than a bottom surface 214b. In a preferred embodiment, an area ratio of the bottom surface 214b to the top surface 214a is in a range of 60% to 90%. The die markings 214 may have a depth 214c in a range of 0.02 to 0.06 millimeters (mm). In particular, the global fiducials 210, the local fiducials 212 and the die markings 214 respectively have edges 210d, 212d, 214d (as indicated by dotted circles in FIGS. 4c, 4d, 4e) without burr on the top surfaces 210a, 212a, 214a so that the global fiducials 210, the local fiducials 212 and the die markings 214 can be precisely identified before bonding the semiconductor dies onto the front surface 2002 of the marked carrier 200. Alternatively, the global fiducials 210, the local fiducials 212 and the die markings 214 may be made temporarily where they can be erased while the front surface 2002 is kept intact, such as by painting or other similar known technologies. After the method S20, the global fiducials 210, the local fiducials 212 and the die markings 214 may be removed by chemical washing without damaging the front surface 2002 of the marked carrier 200; and the marked carrier 200 could be recycled.

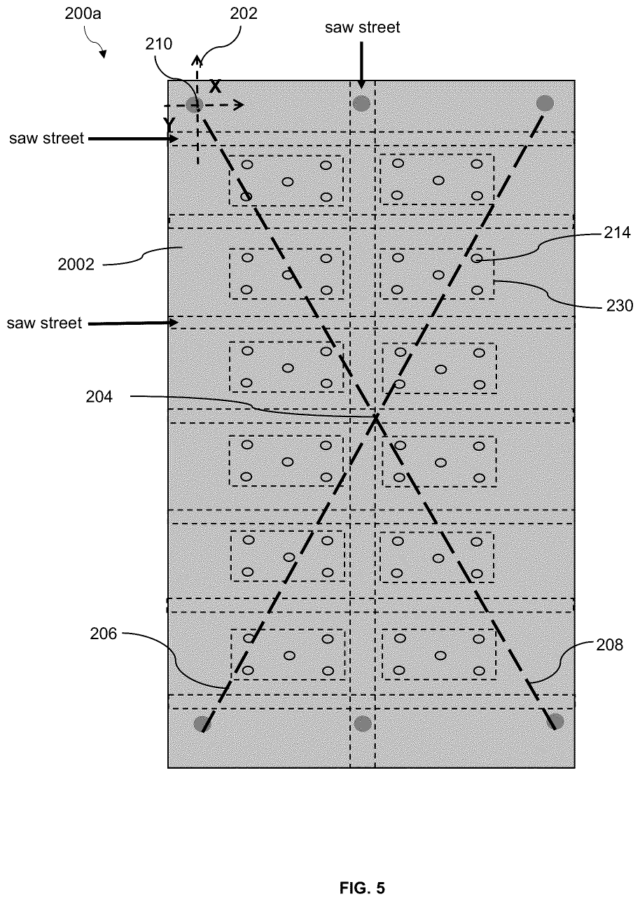

FIG. 5 shows a top view of the marked carrier 200a. The marked carrier 200a has a similar arrangement with the marked carrier 200; however, the marked carrier 200a does not have the local fiducials 212; and thus, the bonding units 220 are not formed on the front surface 2002 of the marked carrier 200a. Instead, the carrier coordinate system 202 is established on the front surface 2002 of the marked carrier 200 according to the global fiducials 210 for deciding the pre-determined locations for mounting the semiconductor dies within the bonding regions 230. Similarly, the carrier coordinate system 202 may have its origin (0, 0) at one of the global fiducials 210 or the carrier center 204 as the intersectional point between the first carrier diagonal line 206 and the second carrier diagonal line 208. Since each bonding region 230 could accommodate one semiconductor die, the marked carrier 200a is used for fabricating SCMs. The SCMs are separated by following saw streets as shown in FIG. 5.

The method S20 includes an optional step of applying a heat release tape (also called thermal release tape) 240 onto the front surface 2002 of the marked carrier 200 or the marked carrier 200a. Similar to the heat release tape 140, the heat release tape 240 on the one hand can be secured to the front surface 2002 of the marked carrier 200; and on the other hand, can secure semiconductor dies on the marked carrier 200 or the marked carrier 200a. Meanwhile, since the semiconductor dies are larger and heavier than the passive components 100, adhesion of the semiconductor dies on the heat release tape 240 could be stronger than that of the heat release tape 140 on the passive components 100. The global fiducials 210, the local fiducials 212 and the die markings 214 may be covered by the heat release tape 240. Preferably, the heat release tape 240 are transparent or semi-transparent so that the global fiducials 210, the local fiducials 212 and the die markings 214 can be seen or detectable. Alternatively, some or all of the global fiducials 210, the local fiducials 212 and the die markings 214 may be not covered by the heat release tape 240.

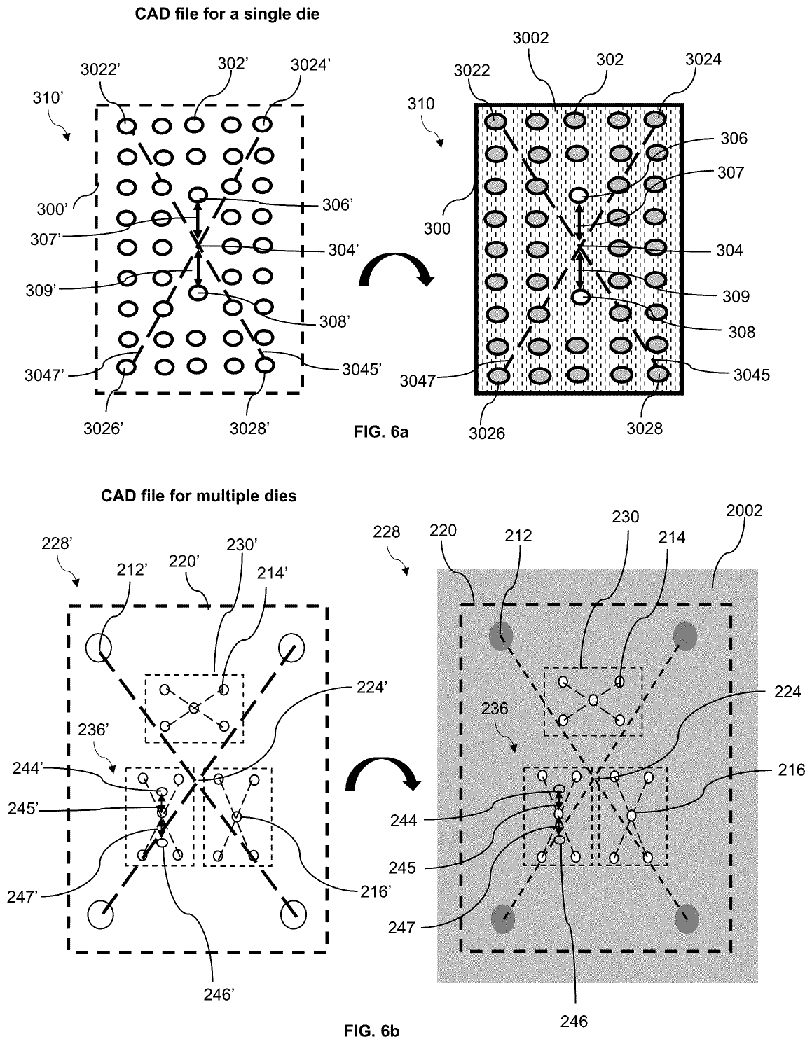

The method S20 includes the Step S22, i.e., retrieving information of a semiconductor die 300 by matching the semiconductor die 300 from a computer-aided design (CAD) die file 300′. FIG. 6a shows a top view of matching the semiconductor die 300 from the CAD die file 300′. It firstly involves matching a die pattern 310 of the semiconductor die 300 from a CAD die pattern 310′ of the CAD die file 300′. In some embodiments, the matching of the die pattern 310 and the CAD die pattern 310′ may be performed by matching die features of the semiconductor die 300 in the die pattern 310 to their corresponding CAD die features of the CAD die file 300′ in the CAD die pattern 310′. In one embodiment, the die features include pre-vias 302 on a die active surface 3002 of the semiconductor die 300. Then, the pre-vias 302 in the die pattern 310 are matched from CAD pre-vias 302′ in the CAD die pattern 310′.

During matching the semiconductor die 300 from the CAD die file 300′, a die center 304 of the semiconductor die 300 may be also matched from a CAD die center 304′ in the CAD die file 300′. The CAD die center 304′ is determined as an intersectional point of a first CAD die diagonal line 3045′ and a second CAD die diagonal line 3047′. The first CAD die diagonal line 3045′ is drawn between a first CAD pre-via 3022′ (corresponding to a first pre-via 3022 on the semiconductor die 300) and a fourth CAD pre-via 3028′ (corresponding to a fourth pre-via 3028 on the semiconductor die 300); and the second CAD die diagonal line 3047′ is drawn between a second CAD pre-via 3024′ (corresponding to a second pre-via 3024 on the semiconductor die 300) and a third CAD pre-via 3026′ (corresponding to a third pre-via 3026 on the semiconductor die 300). Therefore, the die center 304 may be determined by matching from the CAD die center 304′ as an intersectional point of a first die diagonal line 3045 and a second die diagonal line 3047. Then, a first CAD die reference point 306′ and a second CAD die reference point 308′ are determined by shifting a CAD first die offset 307′ and a second CAD die offset 309′ from the CAD die center 304′ respectively. Similarly, the first CAD die reference point 306′ and the second CAD die reference point 308′ are respectively matched to the semiconductor die 300 as a first die reference point 306 and a second die reference point 308. It may be done by respectively matching the CAD first die offset 307′ and the second CAD die offset 309′ to the semiconductor die 300 as a first die offset 307 and a second die offset 309 from the die center 304 on the semiconductor die 300.

FIG. 6b shows that a unit pattern 228 of the bonding units 220 is matched from a CAD unit pattern 228′ of a CAD bonding unit 220′. Firstly, region pattern 236 of the bonding region 230 is matched from a CAD region pattern 236′ of a CAD bonding region 230′. The matching of the region pattern 236 from the CAD region pattern 236′ may be performed by matching region features of the region pattern 236 from their corresponding CAD region features in the CAD region pattern 236′. In one embodiment, the region features include the die markings 214 which are matched from CAD die markings 214′ in the CAD region pattern 236′. In a preferred embodiment, the region features include a central die marking 216 matched from a CAD central die marking 216′. Similarly, a first CAD region reference point 244′ and a second CAD region reference point 246′ of the CAD bonding region 230′ are matched to a first region reference point 244 and a second region reference point 246 of the bonding region 230. The first CAD region reference point 244′ and the second CAD region reference point 246′ are determined by shifting a first CAD region offset 245′ and a second CAD region offset 247′ from the CAD central die marking 216′ respectively. While the first region reference point 244 and the second region reference point 246 are determined by shifting a first region offset 245 and a second region offset 247 from the central die marking 216 respectively. After each of the bonding region 230 in the bonding unit 220 is matched from its respective CAD bonding region 230′ in the CAD bonding unit 220′, the unit pattern 228 of the bonding unit 220 is then matched from the CAD unit pattern 228′ of the CAD bonding unit 220′ by matching unit features in the unit pattern 228 to their corresponding CAD unit features in the CAD unit pattern 228′, so that distribution of the bonding regions 230 is decided within the bonding unit 220. In one embodiment, the unit features include the local fiducials 212 of the bonding units 220 which is matched from CAD local fiducials 212′ of the CAD bonding unit 220′. In another preferred embodiment, the unit features include the unit center 224 of the bonding units 220 which is matched from a CAD unit center 224′ of the CAD bonding unit 220′. Therefore, the die pattern 310, the region pattern 236, and the unit pattern 228 are matched from the CAD die pattern 310′, the CAD region pattern 236′, and the CAD unit pattern 228′ for the semiconductor die 300, the bonding region 230, and the bonding unit 220 respectively.

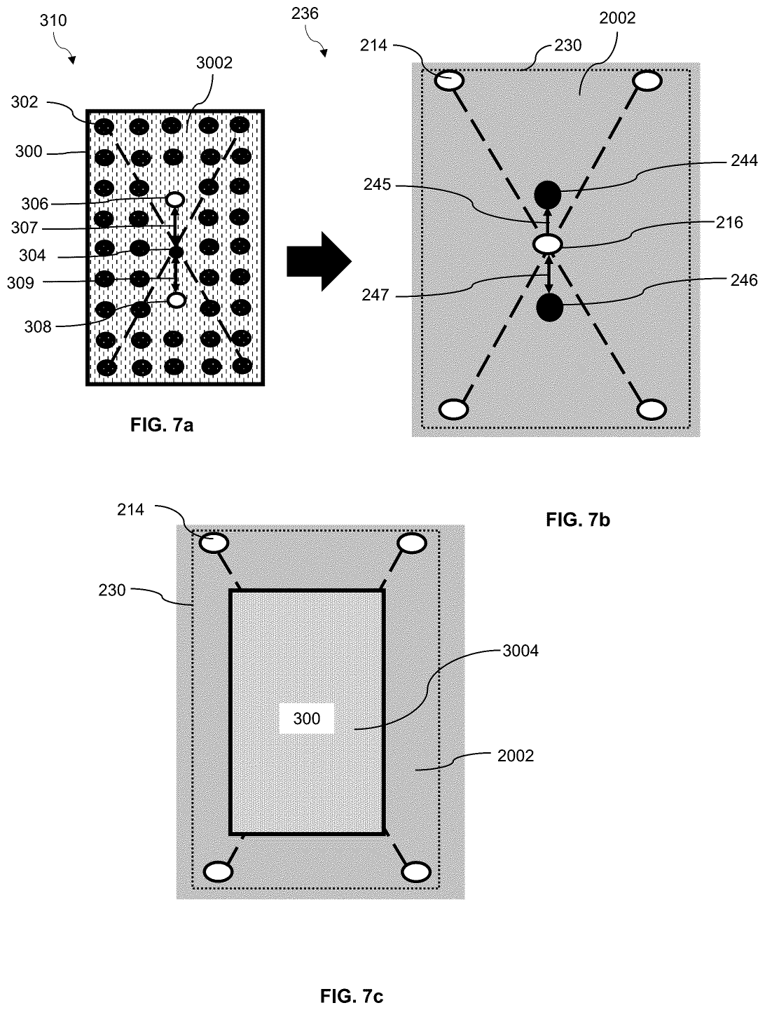

The method S20 includes a first sub-step of the Step S23, i.e., aligning the semiconductor die 300 and/or the passive packages 110 (such as the packaged capacitors 112, the packaged resistors 114, the packaged inductors 116 and the packaged Copper blocks 118) at their corresponding bonding regions 230. FIGS. 7a & 7b show top views of the semiconductor die 300 with the die pattern 310 and the bonding region 230 with the region pattern 236. The semiconductor die 300 is aligned to the bonding region 230 by aligning the die pattern 310 to the region pattern 236. In one embodiment, the alignment is performed by overlying the first die reference point 306 and the second die reference point 308 to the first region reference point 244 and the second region reference point 246, respectively. After the alignment, a second sub-step of the Step S23 is performed, i.e., bonding the semiconductor die 300 and/or the passive packages 110 within the bonding regions 230 on the marked carrier 200 for MCM or on the marked carrier 200a for SCM. FIG. 7c shows a top view that the semiconductor die 300 is bonded to the bonding region 230 in a face-down manner, i.e., the die active surface 3002 of the semiconductor die 300 would be in contact with the front surface 2002 of the marked carrier 200 or the marked carrier 200a. It is also shown that the semiconductor die 300 covers the first region reference point 244 and the second region reference point 246 which are not seen from a die back surface 3004 of the semiconductor die 300 in FIG. 7c.

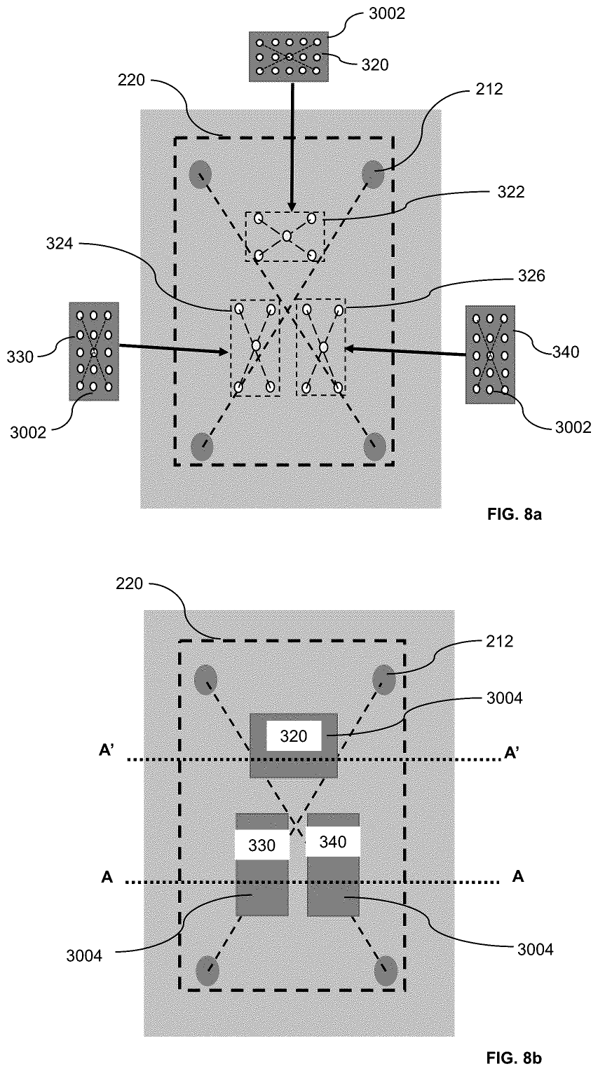

Multiple semiconductor dies 300 and/or the passive packages 110 can be bonded to the bonding units 220 by repeating the alignment described above and bonding each semiconductor die 300 and/or passive packages 110 to its bonding region 230 within the bonding unit 220 in order to fabricate the MCMs. FIG. 8a shows that the semiconductor die 300 includes a first die 320, a second die 330 and a third die 340 which are aligned to a first bonding region 322, a second bonding region 324 and a third bonding region 326 respectively within the bonding unit 220. The alignment is performed as described above in FIGS. 7a & 7b. FIG. 8b shows that the first die 320, the second die 330 and the third die 340 are bonded in the face-down manner in the first bonding region 322, the second bonding region 324 and the third bonding region 326 within the bonding unit 220. It is also shown that the local fiducials 212 of the bonding units 220 are not covered by the first die 320, the second die 330 or the third die 340. Therefore, the local fiducials 212 may be adopted to guide formation of internal electrically couplings among the first die 320, the second die 330 and the third die 340 within the bonding unit 220 for fulling electronic functions of the MCM.

The alignment and the bonding as described above may be conducted by a vision apparatus 400. The vision apparatus 400 can identify the die features such as the pre-vias 302 for the semiconductor die 300, as well as the global fiducials 210, the local fiducials 212 and the die markings 214 for the marked carrier 200 or the marked carrier 200a, in order to determine relative position and orientation of the semiconductor die 300 to the bonding region 230. Preferably, identification of the semiconductor die 300 and the bonding region 230 are performed simultaneously in order to bonding the semiconductor die 300 more precisely at the bonding region 230 on the marked carrier 200 or the marked carrier 200a.

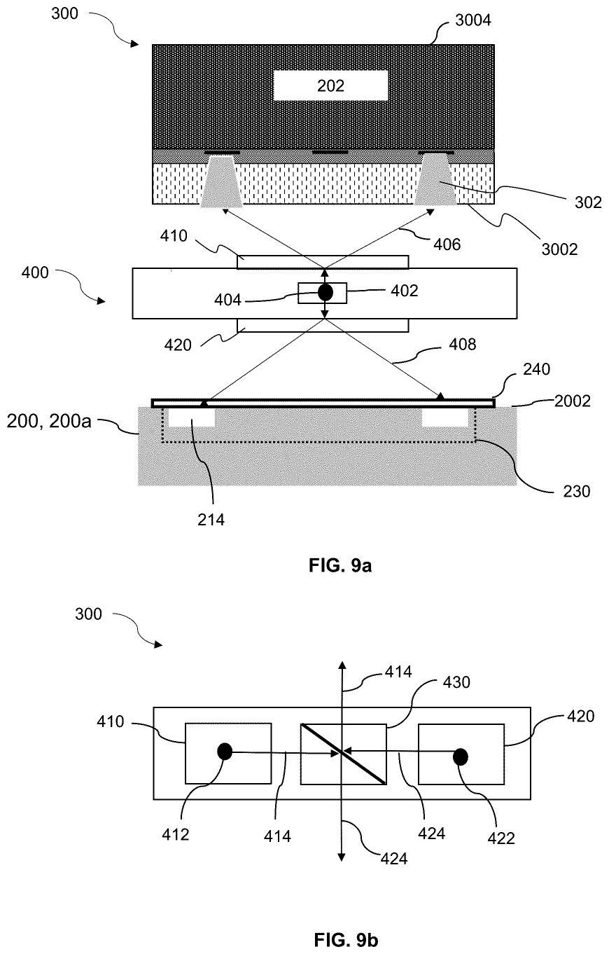

FIG. 9a show a cross-sectional view of an embodiment of the vision apparatus 400 having a lookup camera assembly 410 and a look down camera assembly 420 for simultaneously identifying the pre-vias 302 (with the lookup camera assembly 410) as well as the global fiducials 210, the local fiducials 212 and the die markings 214 (with the lookdown camera assembly 420) when the vision apparatus 400 is inserted between the semiconductor die 300 and the marked carrier 200 or the marked carrier 200a. Once aligned, the vision apparatus 400 is withdrawn; and the semiconductor die 300 is lowered down towards the marked carrier 200 or the marked carrier 200a vertically and finally bonded onto the heat release tape 240 and the front surface 2002 of the marked carrier 200 or the marked carrier 200a. In an embodiment, the lookup camera assembly 410 and the lookdown camera assembly 420 are disposed in a vertical co-axis configuration for avoiding any misalignment that may be caused by the vision apparatus 400 itself. An alignment light 404 is emitted from a single light source 402 and then divided into a lookup beam 406 and a lookdown beam 408 into the lookup camera assembly 410 and the lookdown camera assembly 420 respectively. As a result, the lookup camera assembly 410 and the lookdown camera assembly 420 can simultaneously identify the semiconductor die 300 and its corresponding bonding regions 230 on the marked carrier 200 or the marked carrier 200a. The lookup camera assembly 410 and the lookdown camera assembly 420 have high resolution collinear camera units for precisely determining the position and the orientation of the semiconductor die 300 and the bonding regions 230 respectively.

FIG. 9b shows a cross-sectional view of another embodiment of the vision apparatus 400 having the side-by-side configuration, i.e., the lookup camera assembly 410 and the lookdown camera assembly 420 are arranged in a side-by-side configuration for the vision apparatus 400. The lookup camera assembly 410 and the lookdown camera assembly 420 have a first light source 412 for emitting a first alignment light 414 and a second light source 422 for emitting a second alignment light 424 respectively. Since the first light source 412 and the second light source 422 are independent to each other, the first alignment light 414 and the second alignment light 424 are also distinct to each other. The first alignment light 414 and the second alignment light 424 are controlled to reach a prism 430 and then reflected upwardly and downwardly respectively. Therefore, the lookup camera assembly 410 and the lookdown camera assembly 420 arranged in the side-by-side configuration can also simultaneously identify the semiconductor die 300 and its corresponding bonding region 230 on the marked carrier 200 or the marked carrier 200a. Compared with the vertical co-axis configuration which can only emit the alignment light 404, the side-by-side configuration can independently emit the first and the second alignment lights 414, 424 which could be more suitable for their respective purposes. For example, the first alignment light 414 can be specifically selected for identifying the pre-vias 302; while the second alignment light 424 can be selected with a specific wavelength (such as 600 nm) to penetrate the heat release tape 240 in order to detect the global fiducials 210, the local fiducials 212 and the die markings 214 that are covered by the heat release tape 240.

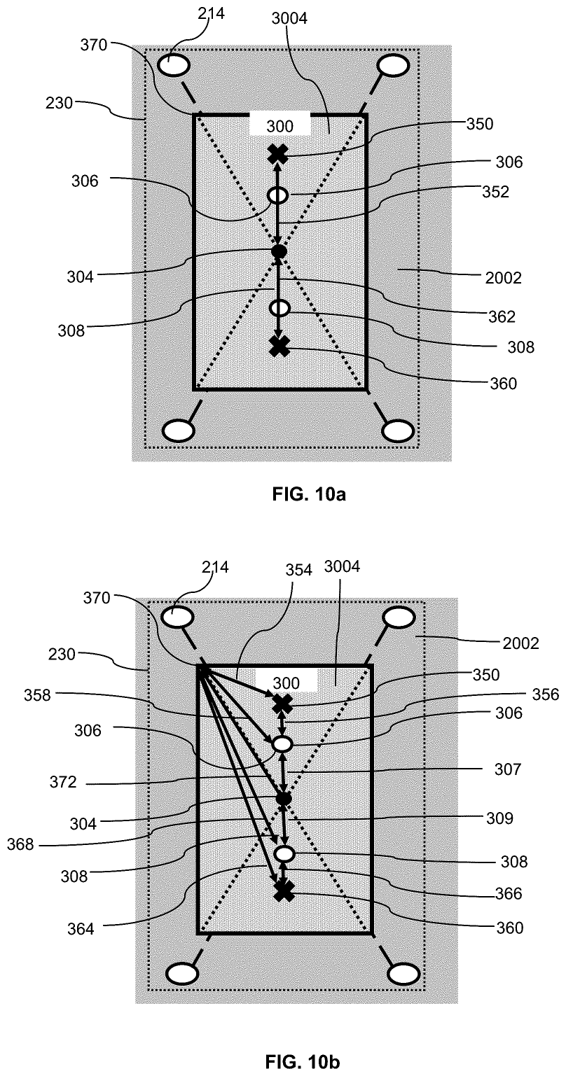

FIGS. 10a & 10b illustrate schematic diagrams of a post-bonding inspection to the semiconductor die semiconductor die 300 bonded in the bonding region 230 on the marked carrier 200 or the marked carrier 200a. The post-bonding inspection is used to inspect whether the semiconductor die 300 are bonded to its green or as-designed position within the bonding region 230. Since the semiconductor die 300 is bonded in the face-down manner, the die back surface 3004 of the semiconductor die 300 covers the first die reference point 306 and the second die reference point 308 on the die active surface 3002 of the semiconductor die 300. Therefore, the first die reference point 306 and the second die reference point 308 cannot be seen directly for the post-bonding inspection. Instead, a first auxiliary reference point 350 and a second auxiliary reference point 360 may be identified, which are different from the first die reference point 306 and the second die reference point 308.

The die center 304 of the semiconductor die 300 may be determined by shifting a first primary auxiliary offset 352 and a second primary auxiliary offset 362 from the first auxiliary reference point 350 and the second auxiliary reference point 360 respectively. FIGS. 10a & 10b show that the die center 304, the first die reference point 306, the second die reference point 308, the first auxiliary reference point 350 and the second auxiliary reference point 360 are aligned in a single line, a first die reference point offset 356 can be determined between the first die reference point 306 and the first auxiliary reference point 350; and then the first primary auxiliary offset 352 is equal to a sum of the first die reference point offset 356 and the first die offset 307. While a second die reference point offset 366 can be determined between the second die reference point 308 and the second auxiliary reference point 360; and then the second primary auxiliary offset 362 is equal to a sum of the second die reference point offset 366 and the second die offset 309.

The first auxiliary reference point 350 and the second auxiliary reference point 360 may be identified from another die feature of the semiconductor die 300 which can be seen directly on the die back surface 3004. FIGS. 10a & 10b show that a corner edge 370 of the semiconductor die 300 is identified as the die feature. Then, the first auxiliary reference point 350 and the second auxiliary reference point 360 are determined by shifting a first secondary auxiliary offset 354 and a second secondary auxiliary offset 364 from the corner edge 370 respectively. Meanwhile, a corner edge-to-center offset 372 can be also determined between the corner edge 370 and the die center 304. Then, a corner edge-to-first die reference point offset 358 can be also determined between the corner edge 370 and the first die reference point 306; and a corner edge-to-second die reference point offset 368 can be also determined between the corner edge 370 and the second die reference point 308. Therefore, the die center 304 and the corner edge 370 as the die features, the first die reference point 306 and the second die reference point 308 as the die reference points, and the first auxiliary reference point 350 and second auxiliary reference point 360 as the auxiliary reference points can be determined with the various offsets as described above among them. Finally, the first die reference point 306 and the second die reference point 308 are compared with the first region reference point 244 and the second region reference point 246 of the bonding region 230 to determine whether the semiconductor die 300 is aligned to the bonding region 230.

In one embodiment, the corner edge 370 may be firstly identified on the die back surface 3004 of the semiconductor die 300, and then the first auxiliary reference point 350 and the second auxiliary reference point 360 are determined by shifting the first secondary auxiliary offset 354 and the second secondary auxiliary offset 364 respectively from the corner edge 370. In the following, the die center 304 can be determined by either shifting the first primary auxiliary offset 352 from the first auxiliary reference point 350 or shifting the second primary auxiliary offset 362 from the second auxiliary reference point 360; and finally, the first die reference point 306 and the second die reference point 308 can be deduced from the die center 304 by shifting the first die offset 307 and the second die offset 309 respectively. Alternatively, the first die reference point 306 and the second die reference point 308 can be deduced by shifting the first die reference point offset 356 and the second die reference point offset 366 from the first auxiliary reference point 350 and the second auxiliary reference point 360 respectively. In another embodiment, the corner edge 370 may be firstly identified on the die back surface 3004 of the semiconductor die 300, and then the die center 304 can be determined by shifting the corner edge-to-center offset 372 from the corner edge 370. Finally, the first die reference point 306 and the second die reference point 308 can be deduced from the die center 304 by shifting the first die offset 307 and the second die offset 309 respectively.

Alternatively, if the die center 304 can firstly identified on the die back surface 3004 of the semiconductor die 300, but the first die offset 307 and the second die offset 309 are not readily available, then the first auxiliary reference point 350 and the second auxiliary reference point 360 are firstly determined by shifting the first primary auxiliary offset 352 and the second primary auxiliary offset 362 respectively from the die center 304; and then the first die reference point 306 and the second die reference point 308 are determined by shifting the first die reference point offset 356 and the second die reference point offset 366 from the first auxiliary reference point 350 and the second auxiliary reference point 360 respectively. It is understood that other choices of identification and determination of the die center 304 and the corner edge 370, the first die reference point 306 and the second die reference point 308, the first auxiliary reference point 350 and the second auxiliary reference point 360, and the various offsets among them as described above are also within the present disclosure.

It is understood that the above descriptions are also applicable to the passive packaged 110. Similar to the semiconductor die 300, passive packages 110 also have package features for the same purpose of the die features as described above for the semiconductor dies 300. The package features may be features of the electrical connections 101 on the bottom surface 1014 which is exposed from the passive packages 110.

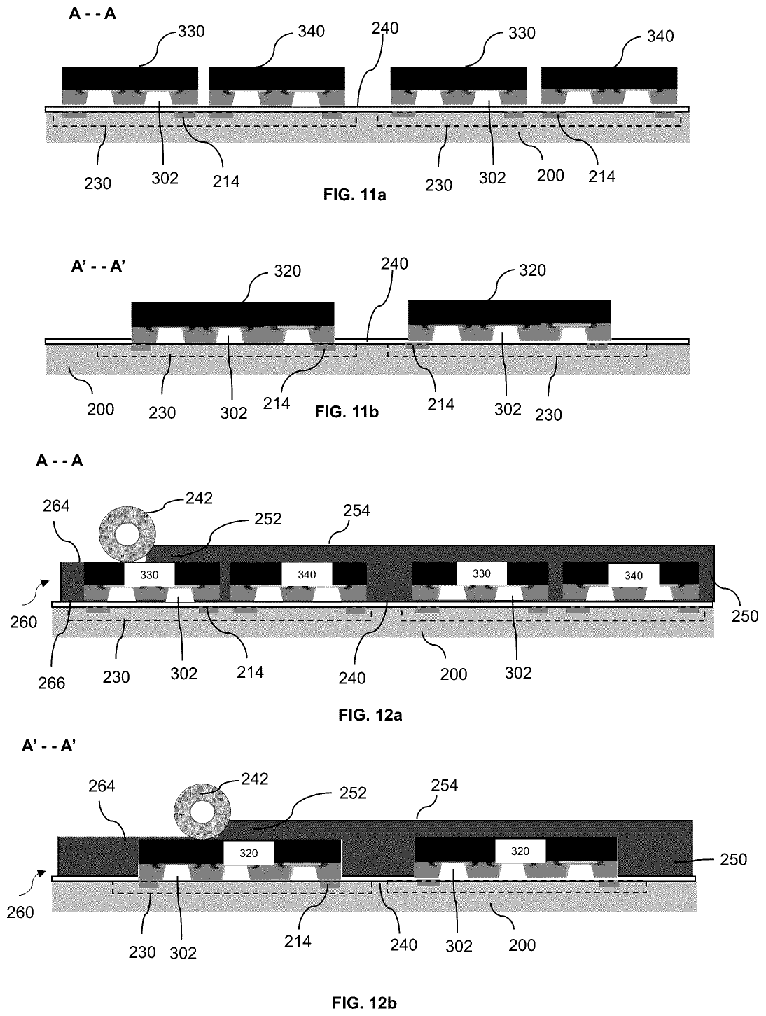

Following the Step 23, the first die 320, the second die 330 and the third die 340 of the semiconductor die 300 are bonded on the marked carrier 200 for fabricating the MCM. For simplification of illustration, the passive packages 110 are not shown in the following figures. But it is understood that the passive packages 110 can be also mounted on the marked carrier 200 for going through all the following processes. FIG. 11a shows a cross-sectional view at a cross-section A-A as indicated in FIG. 8b where the second die 330 and the third die 340 are bonded on the marked carrier 200; while FIG. 11b shows a cross-sectional view of another cross-section A′-A′ indicated in FIG. 8b where the first die 320 is bonded on the marked carrier 200. Since the first die 320, the second die 330 and the third die 340 are bonded in the face-down manner, the pre-vias 302 are covered by the heat release tape 240 and the front surface 2002 of the marked carrier 200.

FIGS. 12a (for the cross-section A-A) & 12b (for the cross-section A′-A′) show cross-sectional views of the Step S24, i.e., forming a molding layer 250 for encapsulating the first die 320, the second die 330 and the third die 340 of the semiconductor die 300 to form a reconstructed panel 260. The molding layer 250 is made of a molding material that is electrically insulating to the first die 320, the second die 330 and the third die 340. Then, the Step S24 optionally includes removing a top portion 252 of the molding layer 250 from a top side 254 of the molding layer 250, so that the reconstructed panel 260 would have a thin profile. It is shown that the top portion 252 is removed from the molding layer 250 by a grinding wheel 242. The grinding may relieve internal stress generated in the molding layer 250; and meanwhile form an inactive side 264 for the reconstructed panel 260 which is ground to have a greater flatness than the top side 254.

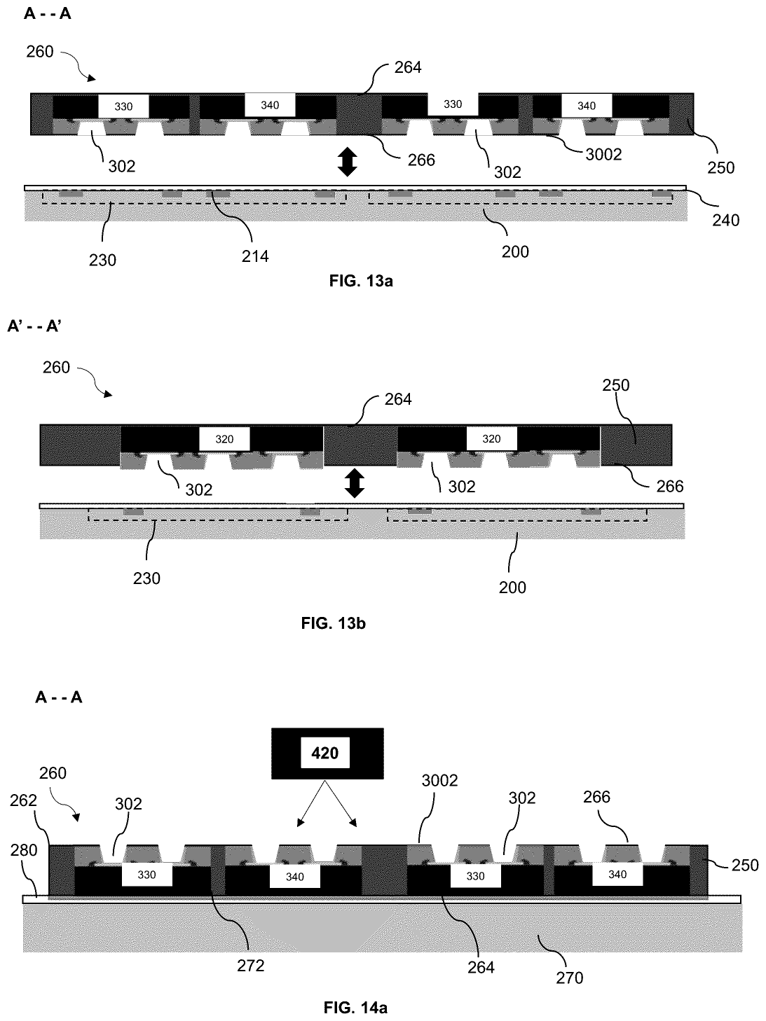

FIGS. 13a (for the cross-section A-A) & 13b (for the cross-section A′-A′) show cross-sectional views of a first sub-step of the Step S25, i.e., releasing the reconstructed panel 260 from the heat release tape 240 and the marked carrier 200. The reconstructed panel 260 would be released from the heat release tape 240 since the heat release tape 240 would lose adhesivity under an elevated temperature (such as at around 200° C.). After being released, an active side 266 of the reconstructed panel 260 including the die active surface 3002 of the semiconductor die 300 (such as the second die 330 and the third die 340 in FIG. 13a; and the first die 320 in FIG. 13b) is exposed from the heat release tape 240 and the marked carrier 200. Accordingly, the pre-vias 302 are exposed from the active side 266 of the reconstructed panel 260. The active side 266 is opposed to the inactive side 264 of the reconstructed panel 260.

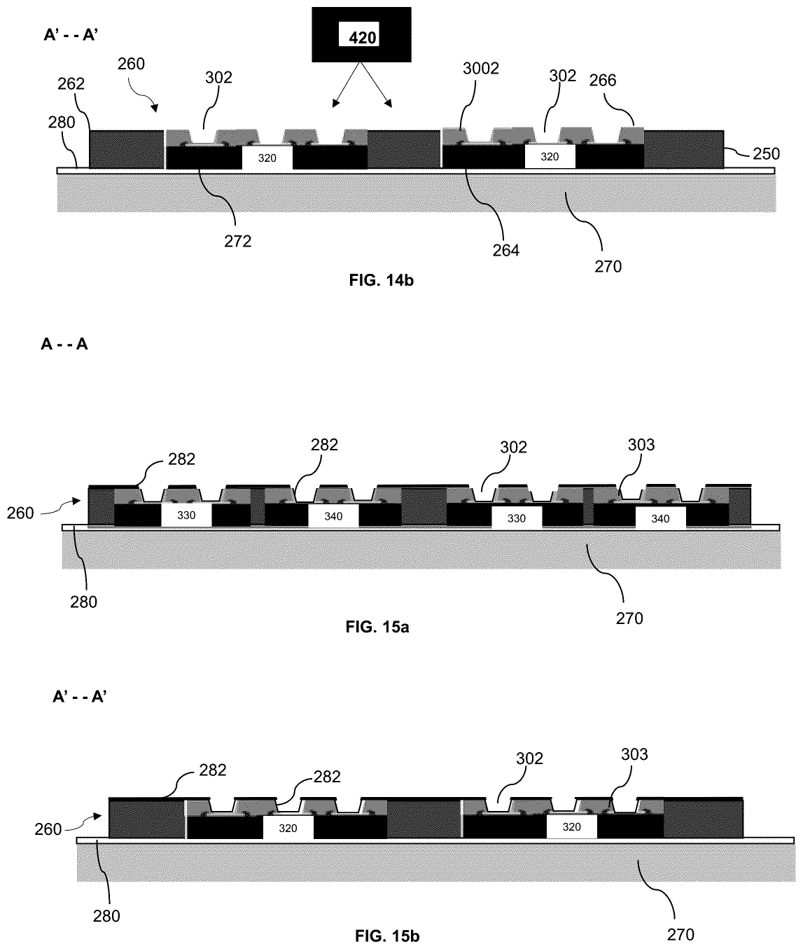

FIGS. 14a (for the cross-section A-A) & 14b (for the cross-section A′-A′) show cross-sectional views of a second sub-step of the Step S25, i.e., transferring the reconstructed panel 260 onto another heat release tape 280 and a carrier plate 270 in a flipped manner, i.e., the inactive side 264 is in contact with the heat release tape 280 and the carrier plate 270, while the active side 266 faces away from the heat release tape 280 and the carrier plate 270 so that the active side 266 including the die active surface 3002 of the semiconductor die 300 is exposed. Accordingly, the pre-vias 302 are exposed from the active side 266 of the reconstructed panel 260. Similar to the heat release tape 240, the heat release tape 280 on the one hand is adhered onto the carrier plate 270; and on the other hand, adheres the reconstructed panel 260 on to the carrier plate 270. Under an elevated temperature (such as at around 200° C.), the reconstructed panel 260 would be released from the heat release tape 280 and the carrier plate 270. In contrast to the marked carrier 200 or the marked carrier 200a, the carrier plate 270 has a clean front surface 272 without any fiducial or marks such as the global fiducials 210, the local fiducials 212 or the die markings 214. Meanwhile, the clean front surface 272 is rather flat to be compatible with the inactive side 264 which also have good flatness due to the grinding as shown in FIGS. 12a & 12b.

FIGS. 14a (for the cross-section A-A) & 14b (for the cross-section A′-A′) also show the Step S26 of performing a die location check (DLC) process to the active side 266 of the reconstructed panel 260 for measuring the locations of the semiconductor die 300 molded in the reconstructed panel 260. The DLC process may be performed by detecting special features of the semiconductor die 300 such as the pre-vias 302. The DLC process may be conducted by the vision apparatus 400 using the lookdown camera assembly 420. Alternatively, the DLC process may be conducted by an independent camera or similar devices suitable for detecting the special features of the semiconductor die 300. The lookdown camera assembly 420 or the independent camera scan the active side 266 of the reconstructed panel 260 for performing the DLC process. After the DLC process, a DLC file is generated by including true positions of the semiconductor die 300 in the reconstructed panel 260 from the measurement of the DLC process, such as the second die 330 and the third die 340 shown in FIG. 14a and the first die 320 shown in FIG. 14b. The DLC file may be stored in a computing apparatus (such as a server) and can be retrieved electronically.

FIGS. 15a (for the cross-section A-A) & 15b (for the cross-section A′-A′) show cross-sectional views of a first sub-step S271 of the Step S27, i.e., forming a thin metal layer 282 on the active side 266 of the reconstructed panel 260. The thin metal layer 282 is formed on the die active surface 3002 of the semiconductor die 300 and also on sidewalls 303 of the pre-vias 302. The thin metal layer 282 is used as a seed layer for facilitating subsequent electroplating processes. The thin metal layer 282 may be a Copper layer or a Copper composite layer such as Titanium (Ti) and Copper. Compared with other features described either above or below, the thin metal layer 282 is very thin and thus will be skipped in the following figures for simplification of illustration.

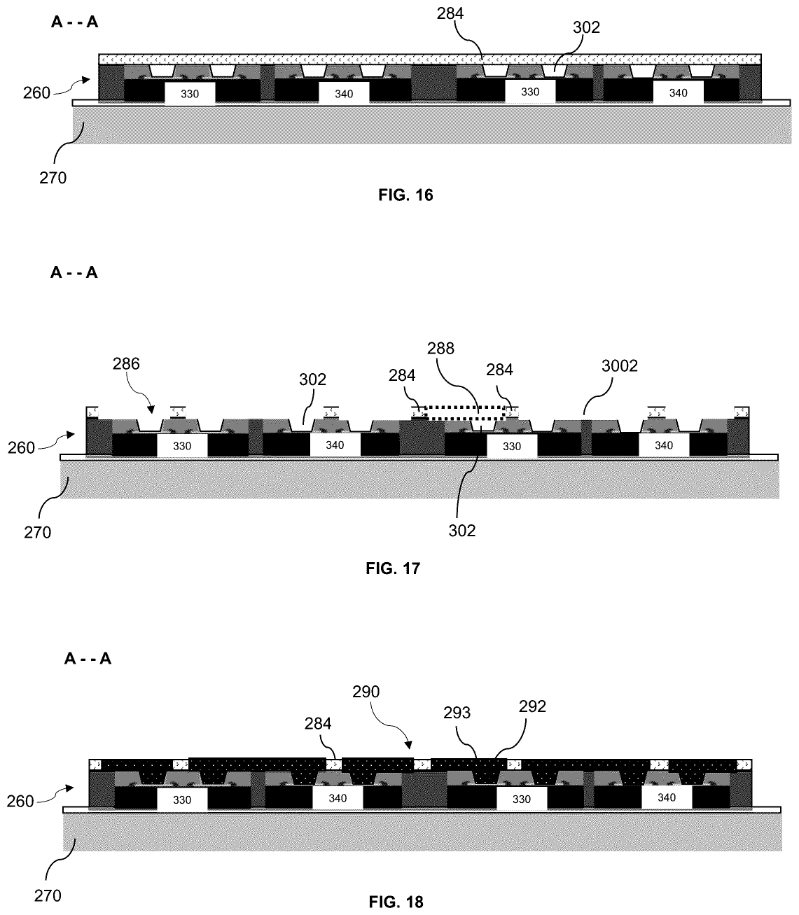

In the following figures, subsequent processes of S20 would be described only for the second die 330 and the third die 340 in the cross-section A-A for simplification of illustration; but it is understood that the same descriptions are applicable for the first die 320 in the cross-section A′-A′. FIG. 16 shows a cross-sectional view of a second sub-step S272 of S27 of forming a first dry film layer 284 on the thin metal layer 282 (not shown) and the active side 266 of the reconstructed panel 260. The pre-vias 302 are covered by the first dry film layer 284. The first dry film layer 284 may be formed by any suitable methods, such as lamination of a dry film material. The first dry film layer 284 is electrically insulating and completely covers the thin metal layer 282 and the active side 266 (including the pre-vias 302).

FIG. 17 shows a cross-sectional view of a third sub-step S273 of the Step S27, i.e., forming a first patterned dry film layer 286 to the first dry film layer 284. The first patterned dry film layer 286 includes multiple first openings 288 (as indicated by the dotted rectangle in FIG. 17) in the first dry film layer 284 corresponding to the pre-vias 302. Therefore, the pre-vias 302 are exposed through the first openings 288. The first patterned dry film layer 286 may be formed by any suitable methods, such as a photoetching process or a laser direct imaging (LDI) process. In particular, an adapted circuit file is generated by transforming a green circuit file according to the DLC file; and the adapted circuit file includes a trace file which further includes precise locations for the first openings 288, so that the first openings 288 could be precisely formed in the first dry film layer 284 according to the trace file. Therefore, the die active surface 3002 of the semiconductor die 300 (such as the second die 330 and the third die 340 as shown) are exposed from the first patterned dry film layer 286 through the pre-vias 302. The green circuit file has green or as-designed information of a circuit layer that would be formed on the die active surface 3002 of the semiconductor die 300; and the green circuit file may be stored in the computing apparatus and can be retrieved electronically for the transformation by the DLC file. The transformation is preferably performed virtually in the computing apparatus where the green circuit file and the DLC file are stored; and then the adapted circuit file is generated and stored in the computing apparatus and may be retrieved from the computing apparatus.

FIG. 18 shows a cross-sectional view of a fourth sub-step S274 of the Step S27, i.e., forming a trace layer 290 according to the trace file of the adapted circuit file, by an electroplating process with electrically conducting materials such as Copper to fill in the first openings 288 of the first patterned dry film layer 286. The trace layer 290 is formed by firstly filling the pre-vias 302 with the electrically conducting materials; and the pre-vias 302 are converted into filled vias 292; and finally, a redistribution layer (RDL) 293 of the trace layer 290 is formed by filling the first openings 288 of the first patterned dry film layer 286 with electrically conducting materials such as Copper. It is shown that the filled vias 292 and the RDL 293 are electrically coupled for leading out the semiconductor die 300.

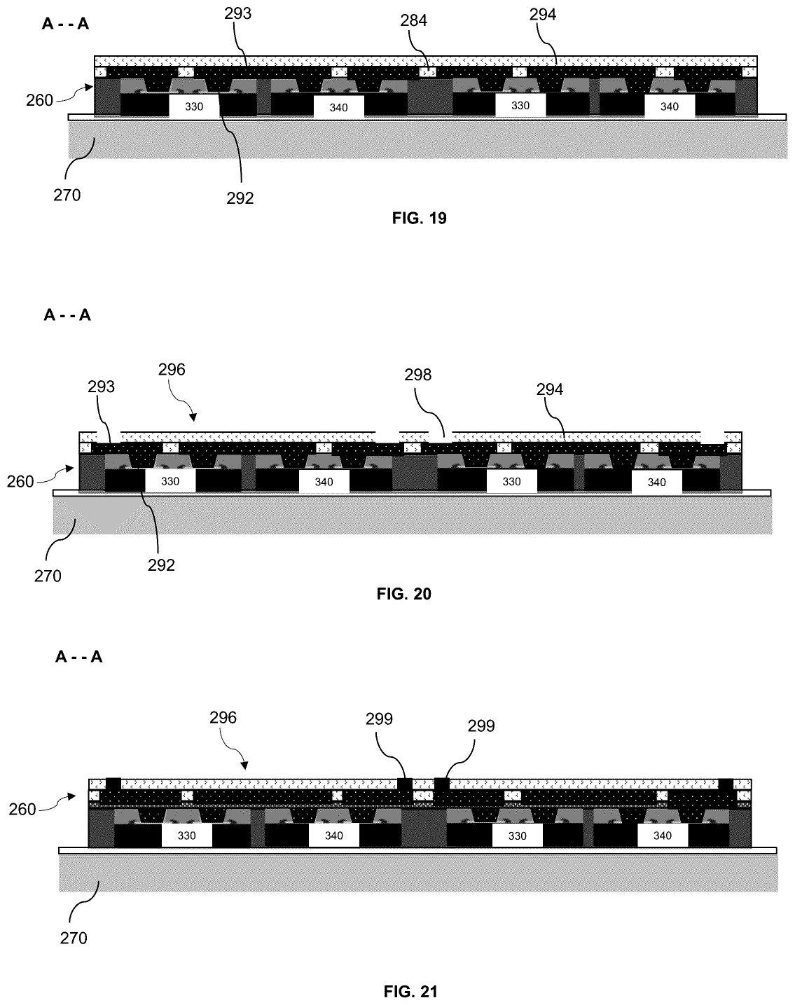

FIG. 19 shows a cross-sectional view of a fifth sub-step S275 of the Step S27, i.e., forming a second dry film layer 294 on the first patterned dry film layer 286 and the RDL 293 of the trace layer 290. The second dry film layer 294 may be formed by any suitable methods, such as lamination of a dry film material. The second dry film layer 294 is also electrically insulating and completely covers the first patterned dry film layer 286 and the RDL 293 of the trace layer 290.

FIG. 20 shows a cross-sectional view of a sixth sub-step S276 of the Step S27 of forming a second patterned dry film layer 296 from the second dry film layer 294. The second patterned dry film layer 296 includes multiple second openings 298 in the second dry film layer 294 for exposing portions of the RDL 293 at pre-determined locations. In addition to the trace file, the adapted circuit file also includes a stud file which could provide precise information of the pre-determined locations for the second openings 298 in the second patterned dry film layer 296, so that the second openings 298 could be precisely formed in the second dry film layer 294. The second patterned dry film layer 296 may be formed by any suitable methods, such as a photoetching process or a laser direct imaging (LDI) process.

FIG. 21 shows a cross-sectional view of a seventh sub-step S277 of the Step S27 of forming a stud layer 299 in the second patterned dry film layer 296 according to the stud file, by filling the second openings 298 with electrically conducting materials such as Copper. Preferably, the same conducting material (such as Copper) is filled into the pre-vias 302, the first openings 288 and the second openings 298, so that the filled vias 292, the RDL 293 and the stud layer 299 would have better electrical compatibility.

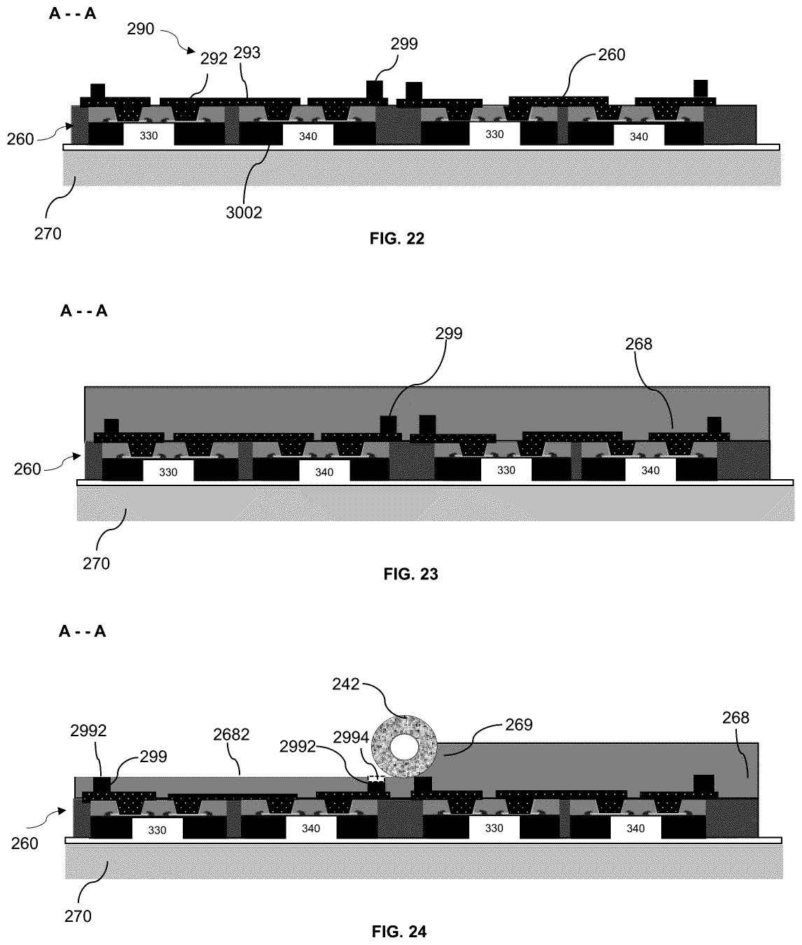

FIG. 22 shows a cross-sectional view of an eighth sub-step S278 of the Step S27 of removing the first patterned dry film 286 and the second patterned dry film 296, leaving the trace layer 290 (including the filled vias 292 and the RDL 293) and the stud layer 299 on the active side 266 of the reconstructed panel 260. Therefore, the die active surface 3002 of the semiconductor die 300 (such as the second die 330 and the third die 340 as shown) could be electrically led out through the filled vias 292 and the RDL 293 of the trace layer 290 as well as the stud layer 299.

FIG. 23 shows a cross-sectional view of a ninth sub-step S279 of the Step S27 of forming a dielectric layer 268 onto the trace layer 290 and the stud layer 299. The dielectric layer 268 is an electrically insulating materials for completely encapsulating the trace layer 290 and the stud layer 299. Preferably, the dielectric layer 268 is made of the same molding material as the molding layer 250.

Optionally, a top portion 269 of the dielectric layer 268 is removed in a grinding process by the grinding wheel 242. FIG. 24 shows a cross-sectional view of the grinding process where a ground surface 2682 is generated for the dielectric layer 268 remaining after the grinding process. As a result, a front surface 2992 of the stud layer 299 is exposed from the dielectric layer 268. The grinding may relieve internal stress generated in the dielectric layer 268. In one embodiment, the ground surface 2682 of the dielectric layer 268 is co-planar with the front surface 2992 of the stud layer 299. In a preferred embodiment, a stud cavity 2994 (as indicated by the dashed rectangle) is formed in the ground surface 2682; and the front surface 2992 is exposed from the stud cavity 2994. The stud cavity 2994 would facilitate formation of solder balls 274 in a subsequent process where a portion of the solder ball 274 would slip inside the stud cavity 2994 to be coupled with the stud layer 299 at the front surface 2992.

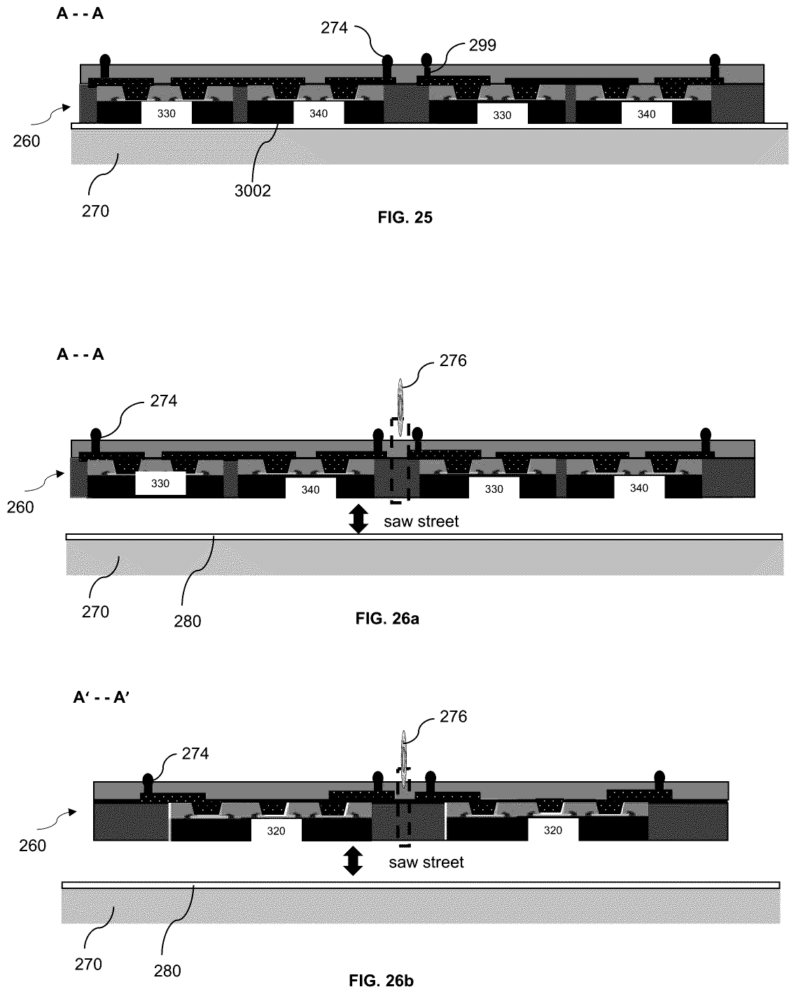

FIG. 25 shows a cross-sectional view of the Step S28 of forming the solder balls 274 as an external connection layer on the stud layer 299. The solder balls 274 are electrically coupled to the stud layer 299, so that the die active surface 3002 of the semiconductor die 300 (such as the second die 330 and the third die 340 as shown) could be electrically led out through the filled vias 292 and the RDL 293 of the trace layer 290, then the stud layer 299, and finally the solder balls 274. The external connection layer may adopt other forms than the solder balls 274, such as surface finish which is suitable for providing a very flat surface as Input/Output (I/O) so as to be connected to external components such as PCB. The adapted circuit file also includes an external connection file which could provide precise information of the external connection layer (such as the solder balls 274 or the surface finish), so that the external connection layer could be precisely formed on the front surface 2992 of the stud layer 299.

Following FIG. 25, FIG. 26a shows a cross-sectional view of the Step S29 of separating the reconstructed panel 260 with the solder balls 274 into individual semiconductor packages (MCMs). The separation may be performed by sawing the reconstructed panel 260 with a saw blade 276 along saw streets as indicated by the dashed rectangle. FIG. 26a shows the separation along the cross-section A-A with the second die 330 and the third die 340. While FIG. 26b shows a cross-sectional view for separating the reconstructed panel 260 along the cross-section A′-A′ with the first die 320. Finally, the separated individual semiconductor packages (MCMs) are released from the carrier plate 270 and the heat release tape 280 under an elevated temperature (such as at around 200° C.) where the heat release tape 280 would lose adhesivity with the separated individual semiconductor packages (MCMs).

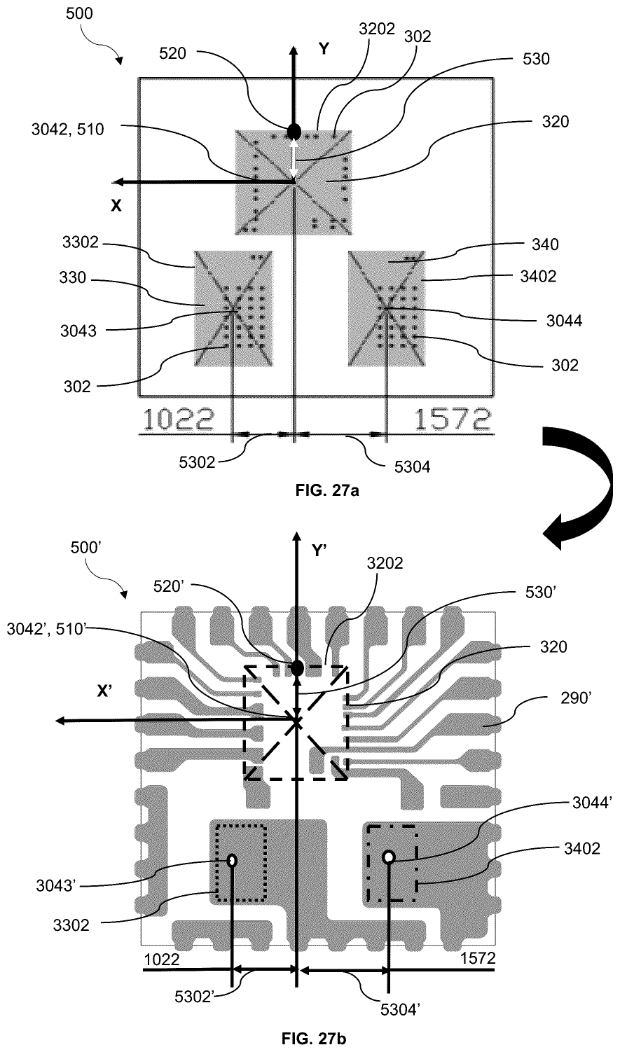

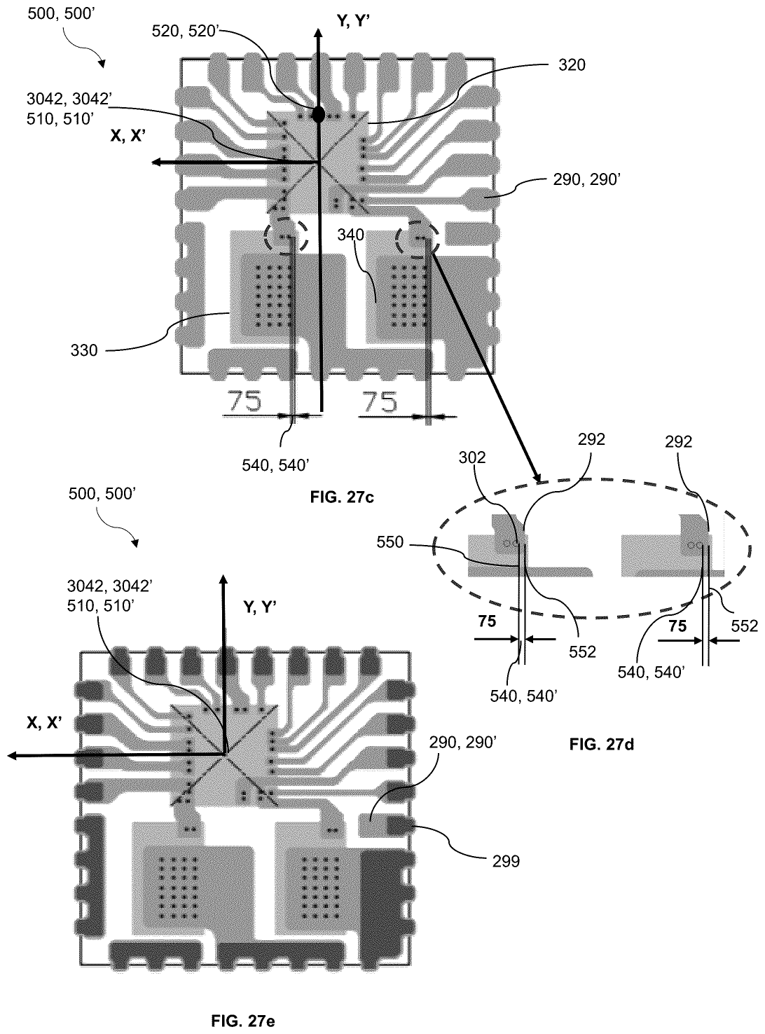

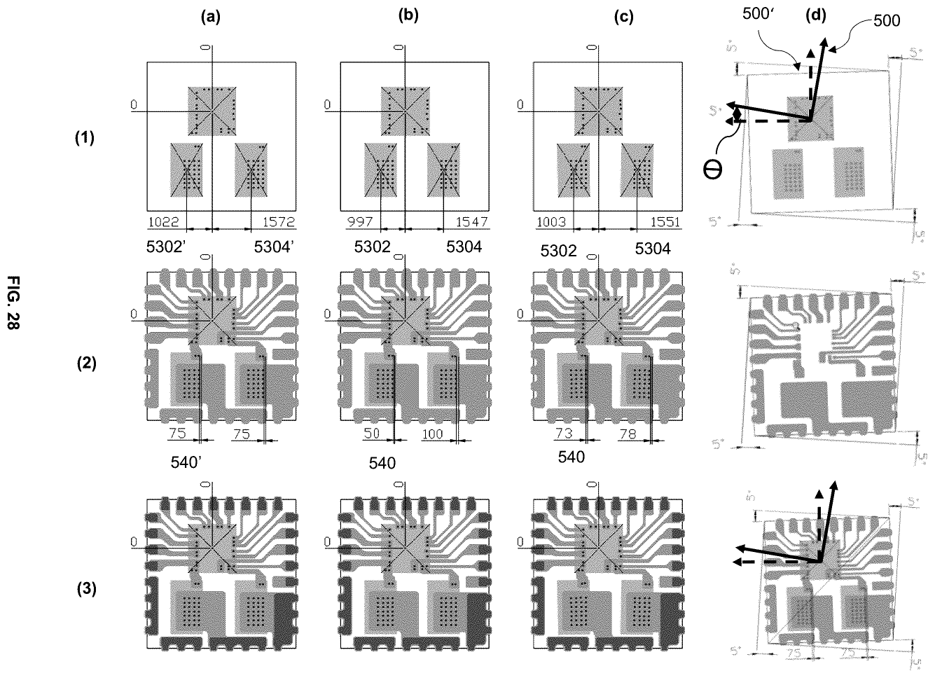

FIGS. 27a to 27e illustrates schematic diagrams of transforming the green circuit file to the adapted circuit file (including the trace file, the stud file and the external connection file) according to the DLC file. FIG. 27a show a top view of an individual semiconductor package (MCM) having the first die 320, the second die 330 and the third die 340. Locations of the first die 320, the second die 330 and the third die 340 within the MCM may be determined by the die features such as the pre-vias 302 which are detected during the DLC process. FIG. 27a shows that a DLC coordinate system 500 is established in the DLC file with a DLC origin (0, 0) 510. In an embodiment, the DLC origin (0, 0) 510 is chosen as the die center 304 of the semiconductor die 300. For example, a first die center 3042 of the first die 320 is shown to be the DLC origin (0, 0) 510 for the DLC coordinate system 500. Alternatively, a second die center 3043 of the second die 330 or a third die center 3044 of the third die 340 can also be chosen as the DLC origin (0, 0) 510 for the DLC coordinate system 500. FIG. 27a shows that a DLC reference point 520 is selected by shifting a DLC offset 530 from the DLC origin (0, 0) 510. For example, the DLC reference point 520 is selected as an intersectional point of the Y-axis of the DLC coordinate system 500 and a first die profile 3202 of the first die 320. Alternatively, the DLC reference point 520 may be selected as an intersectional point of the Y-axis of the DLC coordinate system 500 and a second die profile 3302 of the second die 330, or another intersectional point of the Y-axis of the DLC coordinate system 500 and a third die profile 3402 of the third die 340. It is understood that the selection is arbitrary and any point within the MCM can be selected as the DLC reference point 520. For example, the DLC reference point 520 may be an intersectional point of an X-axis of the DLC coordinate system 500 and the first die profile 3202 of the first die 320. It is also understood that the DLC coordinate system 500, the DLC origin (0, 0) 510, the DLC reference point 520 and the DLC offset 530 are not physically marked on the reconstructed panel 260; instead, they are virtual in nature since the DLC file is generated and then stored in the computing apparatus electronically.

FIG. 27b shows a green circuit file for the MCM. The green circuit file includes a CAD trace file 290′ for forming the trace layer 290 (including the filled vias 292 and the RDL 293), a CAD stud file (not shown) for forming the stud layer 299, and a CAD external connection file (not shown) for forming the external connection layer (such as the solder balls 274). Similarly, a green circuit coordinate system 500′ can be established in the green circuit file; and a CAD first die center 3042′ corresponding to the first die center 3042 of the first die 320 is chosen as a green origin (0, 0) for the green circuit coordinate system 500′. A green reference point 520′ is selected according to the DLC reference point 520 in the DLC file. For example, the green reference point 520′ is selected as an intersectional point of the Y′-axis of the green circuit coordinate system 500′ and the first die profile 3202 (as indicated by the dashed square in FIG. 27b) of the first die 320. The green reference point 520′ is shifted from a green origin (0,0) 510′ by a green offset 530′. It is understood that a CAD second die center 3043′ corresponding to the second die center 3043 or a CAD third die center 3044′ corresponding to the third die center 3044 may be also selected as the green origin (0,0) 510′ of the green circuit coordinate system 500′. It is also understood that the green circuit coordinate system 500′, the green origin (0,0) 510′, the green reference point 520′ and the green offset 530′ are virtual in nature since the green circuit file is stored in the computing apparatus and can be retrieved electronically.

Then, the green circuit file is transformed to the adapted circuit file by aligning the green circuit coordinate system 500′ to the DLC coordinate system 500. The alignment may be performed by aligning any two points in the green circuit coordinate system 500′ and their corresponding two points in the DLC coordinate system 500 respectively. For example, the green origin (0,0) 510′ and the green reference point 520′ in the green circuit coordinate system 500′ are aligned to the DLC origin (0, 0) 510 and the DLC reference point 520 in the DLC coordinate system 500 respectively. As a result, green positions (i.e., as-designed positions) of the first die 320, the second die 330 and the third die 340 in the green circuit file are aligned to their true positions in the DLC file. If the first die 320, the second die 330 and the third die 340 are bonded precisely as they are designed, their true positions in the DLC file overlap with the green positions in the green circuit file. For example, in the DLC file a first DLC die-to-die distance 5302 along the X-axis between the first die center 3042 and the second die center 3043 is 1022 micrometers (μm); and a second DLC die-to-die distance 5304 along the X-axis between the first die center 3042 and the third die center 3044 is 1572 micrometers (μm), as indicated in FIG. 27a. Then, in the green circuit file a first green die-to-die distance 5302′ along the X′-axis between the CAD first die center 3042′ and the CAD second die center 3043′ is kept at 1022 micrometers (μm); and a second green die-to-die distance 5304′ along the X′-axis between the CAD first die center 3042′ and the CAD third die center 3044′ is kept at 1572 micrometers (μm), as indicated in FIG. 27b. In other words, the MCM as shown is aligned ideally without misalignment.

FIG. 27c shows the ideal alignment without misalignment where the DLC origin (0, 0) 510 and green origin (0,0) 510′ are overlapped at the first die center 3042 (or the CAD first die center 3042′) of the first die 320; and the DLC reference point 520 and green reference point 520′ are also overlapped as arbitrarily selected. The trace layer 290 of the circuit layer is formed according to the trace file of the adapted circuit file. Then, the alignment may be also decided by measuring a DLC pre-via-to-trace distance 540 between a tangent line 550 to the pre-vias 302 and an edge line 552 to the RDL 293. FIG. 27d shows an enlarged view of the tangent line 550 to the first die 320, the edge line 552 to the RDL 293, and the DLC pre-via-to-trace distance 540. In the ideal alignment without misalignment, the DLC pre-via-to-trace distance 540 is measured the same as a green pre-via-to-trace distance 540′, such as 75 micrometers (μm) as shown in FIGS. 27c and 27e. It is shown that the first die 320, the second die 330 and the third die 340 are internally electrically coupled for fulling electronic functions of the MCM. Finally, FIG. 27e shows that the stud layer 299 is formed on the trace layer 290 according to the stud file of the adapted circuit file.

FIG. 28 illustrates schematic diagrams of different scenarios of the DLC file, and the trace file and the stud file of the adapted circuit file according to the descriptions of FIGS. 27a to 27e. In FIG. 28, rows (1), (2) and (3) show the DLC file, the trace file and the stud file respectively; while column (a) shows the ideal alignment without misalignment as described in FIGS. 27a to 27e where the DLC file is precisely overlapped with the green circuit file; and columns (b), (c) and (d) show misalignment of a shifting scenario, a shrinkage scenario and a rotational scenario respectively. In the shifting scenario (the column (b)) and the shrinkage scenario (the column (c)), the misalignment may be indicated by the first DLC die-to-die distance 5302 and the second DLC die-to-die distance 5304 along the X-axis obtained from the DLC file (see the row (1)), which are shown to be different from the first green die-to-die distance 5302′ (such as 1022 μm for the example herein) and the second green die-to-die distance; 5304′ (such as 1575 μm for the example herein) from the green circuit file. Alternatively, the misalignment may be indicated by the DLC pre-via-to-trace distance 540 from the DLC file (see the row (2)), which is different from the green pre-via-to-trace distance 540′ from the green circuit file. While in the rotational scenario (column (d)), the misalignment is more conveniently indicated by a rotational angle Θ between the DLC coordinate system 500 (as indicated by the solid lines) and the green circuit coordinate system 500′ (as indicated by the dashed lines). For example, the misalignment is shown to be 5° in column (d). Therefore, the green circuit file is transformed into the adapted circuit file by including the misalignment of the DLC file. The misalignment of the DLC file would be followed in the trace file and the stud file of the adapted circuit file in which the trace layer 290 and the stud layer 299 are formed respectively.

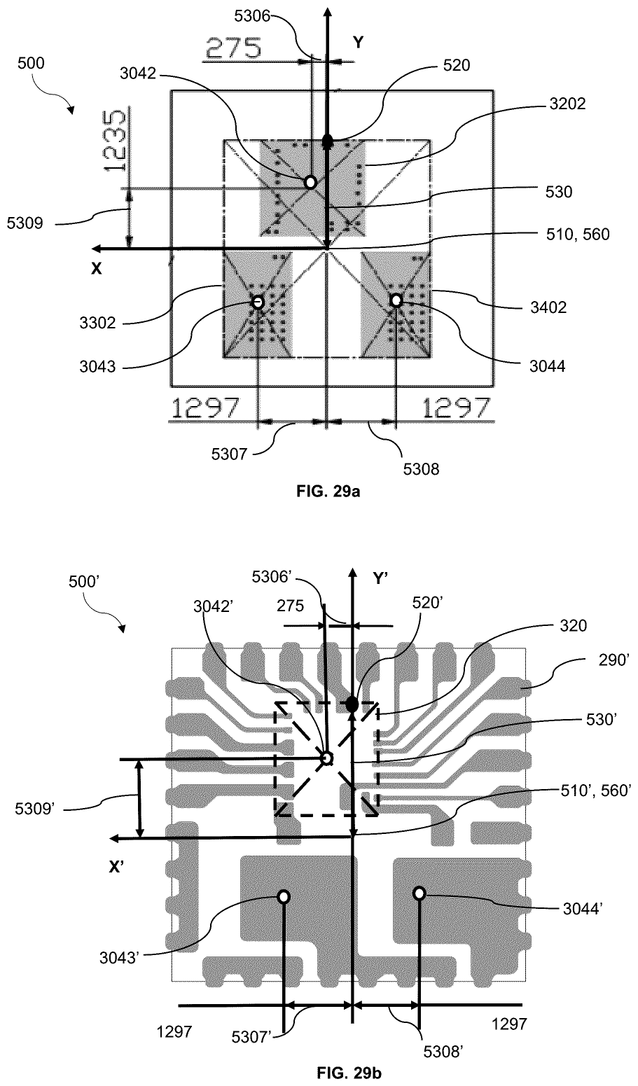

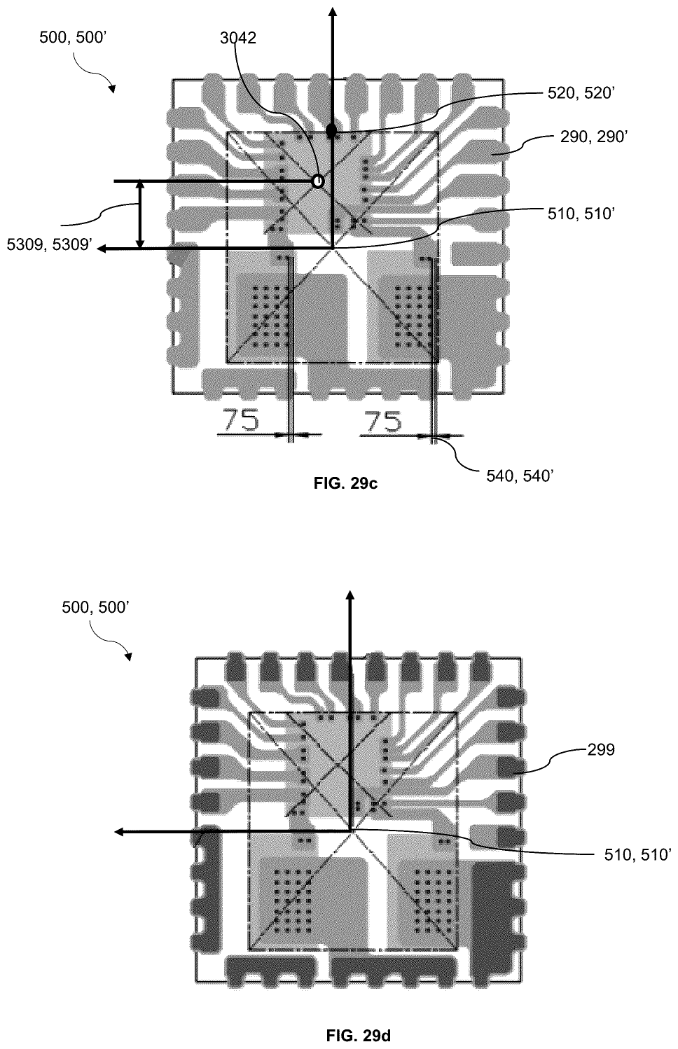

FIGS. 29a to 29d illustrates schematic diagrams of another method of transforming the green circuit file to the adapted circuit file (including the trace file, the stud file and the external connection file) according to the DLC file. FIG. 29a show a top view of the individual semiconductor package (MCM) having the first die 320, the second die 330 and the third die 340. Locations of the first die 320, the second die 330 and the third die 340 within the MCM may be determined by the die features such as the pre-vias 302 which are detected during the DLC process. FIG. 29a shows that the DLC coordinate system 500 is established in the DLC file with the DLC origin (0, 0) 510. In an embodiment, the DLC origin (0, 0) 510 is chosen as a geometric center 560 of the MCM. The geometric center 560 may be identified outside the first die profile 3202 of the first die 320, the second die profile 3302 of the second die 330 and the third die profile 3402 of the third die 340. FIG. 29a also shows that the DLC reference point 520 is selected by shifting the DLC offset 530 from the DLC origin (0, 0) 510. For example, the DLC reference point 520 is selected as an intersectional point of the Y-axis of the DLC coordinate system 500 and the first die profile 3202 of the first die 320. Alternatively, the DLC reference point 520 may be selected as an intersectional point of the Y-axis of the DLC coordinate system 500 and the second die profile 3302 of the second die 330, or another intersectional point of the Y-axis of the DLC coordinate system 500 and the third die profile 3402 of the third die 340. It is understood that the selection is arbitrary and any point within the MCM can be selected as the DLC reference point 520. For example, the DLC reference point 520 may be an intersectional point of the X-axis of the DLC coordinate system 500 and the first die profile 3202 of the first die 320. It is also understood that the DLC coordinate system 500, the DLC origin (0, 0) 510, the DLC reference point 520 and the DLC offset 530 are not physically marked on the reconstructed panel 260; instead, they are virtual in nature since the DLC file is generated and then stored in the computing apparatus electronically.

FIG. 29b shows the green circuit file for the MCM as described above. The green circuit coordinate system 500′ can be established in the green circuit file; and a green geometric center 560′ corresponding to the geometric center 560 is chosen as the green origin (0, 0) for the green circuit coordinate system 500′. The green reference point 520′ is selected according to the DLC reference point 520 in the DLC file. For example, the green reference point 520′ is selected as an intersectional point of the Y′-axis of the green circuit coordinate system 500′ and the first die profile 3202 (as indicated by the dashed rectangle in FIG. 29b) of the first die 320. The green reference point 520′ is shifted from the green origin (0,0) 510′ by the green offset 530′. Alternatively, the green reference point 520′ may be selected as an intersectional point of the Y-axis of the green circuit coordinate system 500′ and the second die profile 3302 (as indicated by the dotted rectangle) of the second die 330, or another intersectional point of the Y-axis of the DLC coordinate system 500 and the third die profile 3402 (as indicated by the dash dotted rectangle) of the third die 340. It is also understood that the green circuit coordinate system 500′, the green origin (0,0) 510′, the green reference point 520′, the green offset 530′ and the green geometric center 560′ are virtual in nature since the green circuit file is stored in the computing apparatus and can be retrieved electronically.

Then, the green circuit file is transformed to the adapted circuit file by aligning the green circuit coordinate system 500′ to the DLC coordinate system 500. The alignment may be performed by aligning any two points in the green circuit coordinate system 500′ and their corresponding two points in the DLC coordinate system 500 respectively. For example, the green origin (0,0) 510′ (or the green geometric center 560′) and the green offset 530′ in the green circuit coordinate system 500′ are aligned to the DLC origin (0, 0) 510 (or the geometric center 560) and the DLC reference point 520 in the DLC coordinate system 500 respectively. As a result, green positions (i.e., as-designed positions) of the first die 320, the second die 330 and the third die 340 in the green circuit file are aligned to their true positions in the DLC file. If the first die 320, the second die 330 and the third die 340 are bonded precisely as what they are designed, their true positions in the DLC file overlap with the green positions in the green circuit file. For example, a first DLC die-to-center distance 5306 along the X-axis between the first die center 3042 and DLC origin (0, 0) 510 (or the geometric center 560) is 275 micrometers (μm); while a second DLC die-to-center distance 5307 along the X-axis between the second die center 3043 and DLC origin (0, 0) 510 (or the geometric center 560) and a third DLC die-to-center distance 5308 along the X-axis between the third die center 3044 and DLC origin (0, 0) 510 (or the geometric center 560) are both 1297 micrometers (μm), as indicated in FIG. 27a. Then, in the green circuit file a first green die-to-center distance 5306′ along the X′-axis between the first die center 3042 and the green origin (0,0) 510′ (or the green geometric center 560′) is kept at 275 micrometers (μm); while a second green die-to-center distance 5307′ along the X′-axis between the second die center 3043 and the green origin (0,0) 510′ (or the green geometric center 560′) and a third green die-to-center distance 5308′ along the X′-axis between the third die center 3044 and the green origin (0,0) 510′ (or the green geometric center 560′) are both kept at 1297 micrometers (μm), as indicated in FIG. 27b. In addition, a fourth DLC die-to-center distance 5309 may be measured along the Y-axis between the first die center 3042 and the DLC origin (0, 0) 510 (or the geometric center 560) is 1235 micrometers (μm). Accordingly, in the green file a fourth green die-to-center distance 5309′ along the Y-axis between the first die center 3042 and the green origin (0, 0) 510′ (or the green geometric center 560′) is kept at 1235 micrometers (μm). In other words, the MCM as shown is aligned ideally without misalignment.

FIG. 29c shows the ideal alignment without misalignment where the DLC origin (0, 0) 510 and green origin (0,0) 510′ are overlapped at the geometric center 560 or the green geometric center 560′, and the DLC reference point 520 and green reference point 520′ are also overlapped as arbitrarily selected. The trace layer 290 of the circuit layer is formed according to the trace file of the adapted circuit file. Then, the alignment may be also decided by measuring the DLC pre-via-to-trace distance 540 as described above between the tangent line 550 to the pre-vias 302 and the edge line 552 to the RDL 293. In the ideal alignment without misalignment, the DLC pre-via-to-trace distance 540 is measured the same as the green pre-via-to-trace distance 540′, such as 75 micrometers (μm) as shown in FIG. 29c. It is shown that the first die 320, the second die 330 and the third die 340 are internally electrically coupled for fulling electronic functions of the MCM. Finally, FIG. 29d shows that the stud layer 299 is formed on the trace layer 290 according to the stud file of the adapted circuit file.

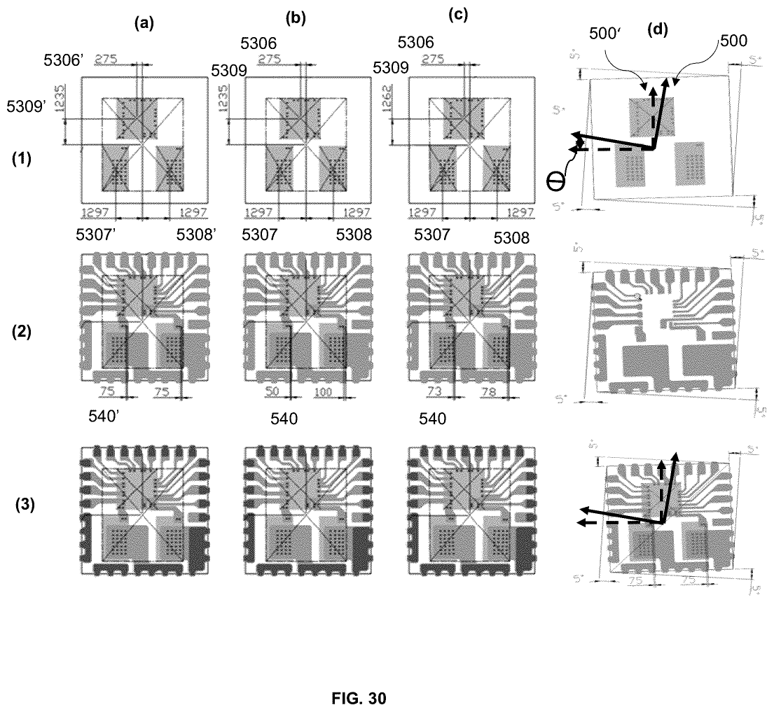

FIG. 30 illustrates schematic diagrams of different scenarios of the DLC file, and the trace file and the stud file of the adapted circuit file according to the descriptions of FIGS. 29a to 29d. In FIG. 30, rows (1), (2) and (3) show the DLC file, the trace file and the stud file respectively; while column (a) shows the ideal alignment without misalignment as described in FIGS. 29a to 29d where the DLC file is precisely overlapped with the green circuit file; and columns (b), (c) and (d) show misalignment of the shifting scenario, the shrinkage scenario and the rotational scenario respectively. In the shifting scenario (the column (b)) and the shrinkage scenario (the column (c)), the misalignment may be indicated by the first DLC die-to-center distance 5306 and the second or the third DLC die-to-center distance 5307, 5308 along the X-axis, as well as the fourth DLC die-to-center distance 5309 along the Y-axis obtained from the DLC file (see the row (1)). Alternatively, the misalignment may be indicated by the DLC pre-via-to-trace distance 540 from the DLC file (see the row (2)). While in the rotational scenario (column (d)), the misalignment is more conveniently indicated by the rotational angle Θ between the DLC coordinate system 500 (as indicated by the solid lines) and the green circuit coordinate system 500′ (as indicated by the dashed lines). For example, the misalignment is shown to be 5° in column (d). Therefore, the green circuit file is transformed into the adapted circuit file by including the misalignment of the DLC file. The misalignment of the DLC file would be followed in the trace file and the stud file of the adapted circuit file in which the trace layer 290 and the stud layer 299 are formed respectively.

In the embodiment that the DLC origin (0, 0) 510 is chosen as the die center 304 of the semiconductor die 300 in the MCM, it is necessary to determine the true position of the semiconductor die 300 only (such as the first die 320 as described in FIGS. 27a to 27e) in the DLC process. While the DLC process may be not performed on other semiconductor dies (such as the second die 330 or the third die 340) in the MCM, and the other semiconductor dies simply follow their green positions. As a result, the DLC process can be performed in a faster manner for enhancing efficiency of the DLC process. If the DLC origin (0, 0) 510 is chosen as the geometric center 560 of the MCM, then it is required that the DLC process should be performed to all the true positions of the semiconductor dies 300 in the MCM.

It is understood that the panel-level semiconductor packaging method S20 as described above is also applicable for the passive packages 110 as made from the method S10, such as the packaged capacitors 110, the packaged resistors 112, the packaged inductors 116 and the packaged Copper blocks 118. The MCMs and the SCMs may include one or more passive packages 110, in addition to the semiconductor die(s) 300.

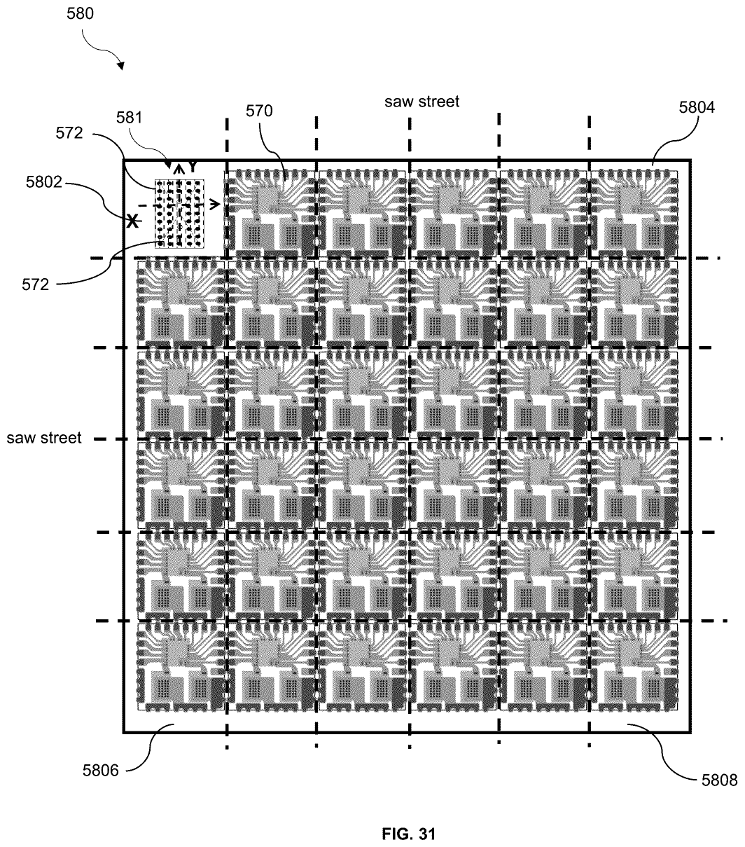

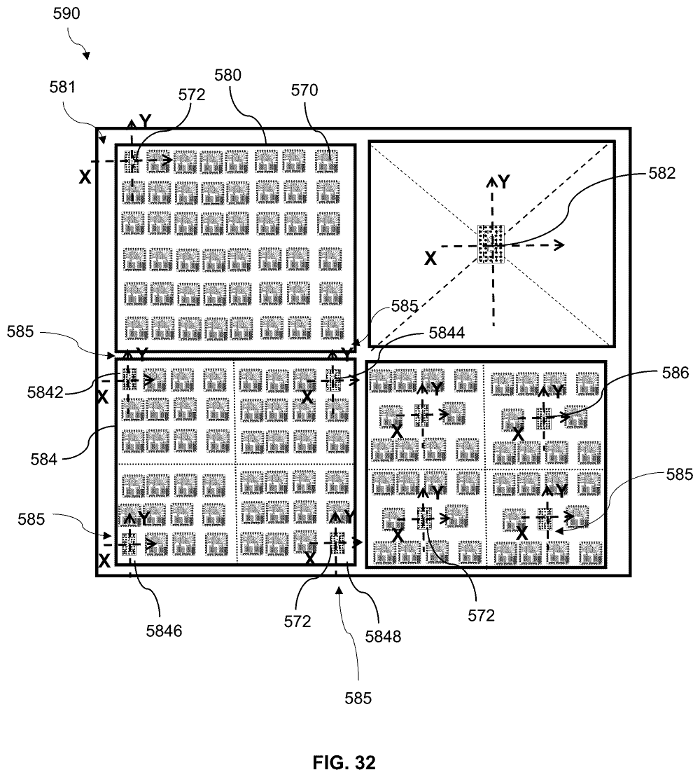

FIG. 31 illustrates a schematic diagram of a block 580 having multiple semiconductor packages (MCMs) 570. A reference package 572 may be packaged in the block 580 for establishing a block coordinate system 581. As a result, positions of the semiconductor packages (MCMs) 570 in the block 580 are determined by their coordinates (x, y) in the block coordinate system 581; and then saw streets (as indicated by the dashed lines) could be decided according to the positions of the semiconductor packages (MCMs) 570. FIG. 31 shows that the reference package 572 is located at a first block corner 5802 of the block 580. It is understood that the reference package 572 may be at another block corner of the block 580, such as a second block corner 5804, a third block corner 5806, or a fourth block corner 5808. Alternatively, the reference package 572 may be at a block center 582 of the block 580 (shown in FIG. 32). Finally, the block 580 is separated into the individual semiconductor packages (MCMs) 570 along the saw streets.

FIG. 32 illustrate a schematic diagram of a panel 590 having multiple blocks 580 as described above. The block 580 further have multiple sub-blocks 584 each of which have multiple semiconductor packages (MCMs) 570. It is shown that the panel 590 is divided into four blocks 580; but it is understood that the panel 590 may be divided into other numbers of the block 580, such as nine blocks 580. The block 580 may be further divided into multiple sub-blocks 584, such as four sub-blocks 584 as shown. But it is understood that the block 580 may be divided into other numbers of the sub-blocks 584, such as nine. Each sub-block 584 may include at least one reference package 572 for establishing a sub-block coordinate system 585. As a result, positions of the semiconductor packages (MCMs) 570 in the sub-blocks 584 are determined by their coordinates (xx, yy) in the sub-block coordinate system 585; and then saw streets (not shown) could be decided according to the positions of the semiconductor packages (MCMs) 570. FIG. 32 shows that the reference package 572 is located at a first sub-block corner 5842 of the sub-blocks 584. It is understood that the reference package 572 may be at other sub-block corner of the sub-blocks 584, such as a second sub-block corner 5844, a third sub-block corner 5846, or a fourth sub-block corner 5848 of the sub-blocks 584. Alternatively, the reference package 572 may be at a sub-block center 586 of the sub-blocks 584. In addition, the position of the sub-blocks 584 in the block 580 can be represented by establishing a relationship between the sub-block coordinate system 585 and the block coordinate system 581. For example, if an origin (0, 0) of the sub-block coordinate system 585 has a coordinate (x, y) in the block coordinate system 581, then the coordinate (xx, yy) in the sub-block coordinate system 585 would be adjusted by the coordinate (x, y) in order to be represented in the block coordinate system 581. Finally, the block 580 is separated into the individual semiconductor packages (MCMs) 570 along the saw streets. The sub-blocks 584 may be further divided into smaller units each of which includes the reference package 572 for establishing a coordinate system for the smaller unit. But it is understood that the more the smaller units that are divided, the more reference package 572 would be included, and the less semiconductor packages (MCMs) 570 could be produced on the panel 590, which would result in a lower overall production efficiency.

In the application, unless specified otherwise, the terms “comprising”, “comprise”, and grammatical variants thereof, intended to represent “open” or “inclusive” language such that they include recited elements but also permit inclusion of additional, non-explicitly recited elements.

As used herein, the term “about”, in the context of concentrations of components of the formulations, typically means+/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. The description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

It will be apparent that various other modifications and adaptations of the application will be apparent to the person skilled in the art after reading the foregoing disclosure without departing from the spirit and scope of the application and it is intended that all such modifications and adaptations come within the scope of the appended claims.

### REFERENCE NUMERALS

100 passive components;
101 electrical connections;
   1012 front surface;
   1014 bottom surface;
102 capacitors;
104 resistors;
106 inductors;
108 Copper blocks;
110 passive packages;
112 packaged capacitors;
114 packaged resistors;
116 packaged inductors;
118 packaged Copper blocks;
120 substrate;
122 front surface;
124 substrate center;
126 first diagonal line;
128 second diagonal line;
130 global fiducials;
   1302 first global fiducial;
   1304 second global fiducial;
   1306 third global fiducial;
   1308 fourth global fiducial;
131 substrate coordinate system;
132 first dashed rectangle;
   1322 first location center;
   1324 first location corner;
134 second dashed rectangle;
   1342 second location center;
   1344 second location corner;
136 third dashed rectangle;
   1362 third location center;
   1364 third location corner;
138 fourth dashed rectangle;
   1382 fourth location center;
   1384 fourth location corner;
140 heat release tape;
142 grinding wheel;
144 saw blade;
150 encapsulation layer;
152 top portion;
154 top side;
160 molded structure;
162 vias;
164 front side;
166 bottom side;
200 marked carrier (MCM);
200a marked carrier (SCM);
   2002 front surface;
202 carrier coordinate system;
204 carrier center;
206 first carrier diagonal line;
208 second carrier diagonal line;
210 global fiducials;
   210a top surface;
   210b bottom surface;
   210c depth;
   210d edge;
212 local fiducials;
   212a top surface;
   212b bottom surface;
   212c depth;
   212d edge;
212′ CAD local fiducials;
214 die markings;
   214a top surface;
   214b bottom surface;
   214c depth;
   214d edge;
214′ CAD die markings;
216 central die marking;
216′ CAD central die marking;
220 bonding unit(s);
220′ CAD bonding unit(s);
222 unit coordinate system;
224 unit center;
224′ CAD unit center;
226 first unit diagonal line;
227 second unit diagonal line;
228 unit pattern;
228′ CAD unit pattern;
230 bonding region(s);
230′ CAD bonding region(s);
236 region pattern;
236′ CAD region pattern;
240 heat release tape;
242 grinding wheel;
244 first region reference point;
244′ first CAD region reference point;
245 first region offset;
245′ first CAD region offset;
246 second region reference point;
246′ second CAD region reference point;
247 second region offset;
247′ second CAD region offset;
250 molding layer;
252 top portion;
254 top side;
260 reconstructed panel;
264 inactive side;
266 active side;
268 dielectric layer;
   2682 ground surface;
269 top portion;
270 carrier plate;
272 clean front surface;
274 solder balls;
276 saw blade;
280 heat release tape;
282 thin metal layer;
284 first dry film layer;
286 first patterned dry film layer;
288 first openings;
290 trace layer;
290′ CAD trace file;
292 filled vias;
293 redistribution layer (RDL);
294 second dry film layer;
296 second patterned dry film layer;
298 second openings;
299 stud layer;
   2992 front surface;
   2994 stud cavity;
300 semiconductor die;
300′ CAD die file;
   3002 die active surface;
   3004 die back surface;
302 pre-vias;
302′ CAD pre-vias;
   3022 first pre-via;
   3022′ first CAD pre-via;
   3024 second pre-via;
   3024′ second CAD pre-via;
   3026 third pre-via;
   3026′ third CAD pre-via;
   3028 fourth pre-via;
   3028′ fourth CAD pre-via;
303 sidewalls;
304 die center;
304′ CAD die center;
   3042 first die center;
   3042′ CAD first die center;
   3043 second die center;
   3043′ CAD second die center;
   3044 third die center;
   3044′ CAD third die center;
   3045 first die diagonal line;
   3045′ first CAD die diagonal line;
   3047 second die diagonal line;
   3047′ second CAD die diagonal line;
306 first die reference point;
306′ first CAD die reference point;
307 first die offset;
307′ CAD first die offset;
308 second die reference point;
308′ second CAD die reference point;
309 second die offset;
309′ second CAD die offset;
310 die pattern;
310′ CAD die pattern;
320 first die;
   3202 first die profile;
330 second die;
   3302 second die profile;
340 third die;
   3402 third die profile;
322 first bonding region;
324 second bonding region;
326 third bonding region;
350 first auxiliary reference point;
352 first primary auxiliary offset;
354 first secondary auxiliary offset;
356 first die reference point offset;
358 corner edge-to-first die reference point offset;
360 second auxiliary reference point;
362 second primary auxiliary offset;
364 second secondary auxiliary offset;
366 second die reference point offset;
368 corner edge-to-second die reference point offset;
370 corner edge;
372 corner edge-to-center offset;
400 vision apparatus;
402 single light source;
404 alignment light;
406 lookup beam;
408 lookdown beam;
410 lookup camera assembly;
412 first light source;
414 first alignment light;
420 lookdown camera assembly;
422 second light source;
424 second alignment light;
430 prism;
500 DLC coordinate system;
500′ green circuit coordinate system;
510 DLC origin (0, 0);
510′ green origin (0,0);
520 DLC reference point;
520′ green reference point;
530 DLC offset;
530′ green offset;
   5302 first DLC die-to-die distance;
   5302′ first green die-to-die distance;
   5304 second DLC die-to-die distance;
   5304′ second green die-to-die distance;
   5306 first DLC die-to-center distance;
   5306′ first green die-to-center distance;
   5307 second DLC die-to-center distance;
   5307′ second green die-to-center distance;
   5308 third DLC die-to-center distance;
   5308′ third green die-to-center distance;
   5309 fourth DLC die-to-center distance;
   5309′ green die-to-center distance;
540 DLC pre-via-to-trace distance;
540′ green pre-via-to-trace distance;
550 tangent line;
552 edge line;
560 geometric center;
560′ green geometric center;
570 semiconductor packages (MCMs);
572 reference package;
580 block;
   5802 first block corner;
   5804 second block corner;
   5806 third block corner;
   5808 fourth block corner;
581 block coordinate system;
582 block center;
584 sub-blocks;
   5842 first sub-block corner;
   5844 second sub-block corner; not
   5846 third sub-block corner;
   5848 fourth sub-block corner;
585 sub-block coordinate system;
586 sub-block center;
590 panel;

What is claimed is:

1. A method of forming a circuit layer on a plurality of semiconductor devices for an electronic module, comprising:
generating a die location check (DLC) file which comprises true positions of the semiconductor devices in a reconstructed panel;
retrieving a green circuit file having green positions for the semiconductor devices;
transforming the green circuit file to an adapted circuit file using the DLC file, wherein the green positions are aligned to the true positions for the semiconductor devices; and
forming the circuit layer on the semiconductor devices at the true positions according to the adapted circuit file.

2. The method of claim 1, wherein transforming the green circuit file to an adapted circuit file further comprises:
identifying a die location check (DLC) coordinate system in the DLC file;
identifying a green circuit coordinate system in the green circuit file; and
aligning the green circuit coordinate system to the DLC coordinate system for aligning the green positions to the true positions.

3. The method of claim 2, wherein aligning the green circuit coordinate system to the DLC coordinate system further comprises:
identifying a DLC origin for the DLC coordinate system;
determining a DLC reference point for the DLC coordinate system;
retrieving a green origin for the green circuit coordinate system according to the DLC origin;
determining a green reference point for the green circuit coordinate system; and
aligning the green origin and the green reference point to the DLC origin and the DLC reference point, respectively.

4. The method of claim 3, wherein the electronic module comprises a multiple chip module (MCM), and the DLC origin is configured to be a die center of a selected semiconductor die of the MCM.

5. The method of claim 3, wherein the electronic module comprises a multiple chip module (MCM), and the DLC origin is configured to be a geometric center of the MCM.

6. The method of claim 4, wherein the DLC reference point is configured to be an intersectional point of an X-axis or a Y-axis of the DLC coordinate system and a die profile of the selected semiconductor die.

7. The method of claim 3, wherein the adapted circuit file comprises a trace file for forming a trace layer (RDL) on the semiconductor devices, and a stud file for forming a stud layer on the trace layer, wherein the trace layer and the stud layer are electrically coupled for leading out the semiconductor devices.

8. The method of claim 1, further comprising:
conducting a post-bonding inspection for inspecting the semiconductor devices bonded on a marked carrier before forming the reconstructed panel.

9. The method of claim 8, wherein the semiconductor devices comprise a semiconductor die, and the post-bonding inspection is conducted by:
identifying a corner edge of the semiconductor die;
determining a die center of the semiconductor die by shifting a corner edge-to-center offset from the corner edge;
determining a first die reference point and a second die reference point by shifting a first die offset and a second die offset from the die center respectively; and
determining whether the first die reference point and the second die reference point are aligned to a first region reference point and a second region reference point on the marked carrier.

10. The method of claim 8, wherein the semiconductor devices comprise a semiconductor die, and the post-bonding inspection is conducted by:
identifying a corner edge of the semiconductor die;
determining a first auxiliary reference point and a second auxiliary reference point by shifting a first secondary auxiliary offset and a second secondary auxiliary offset from the corner edge respectively;
determining a first die reference point and a second die reference point by shifting a first die reference point offset and a second die reference point offset from the first auxiliary reference point and the second auxiliary reference point, respectively; and
determining whether the first die reference point and the second die reference point are aligned to a first region reference point and a second region reference point on the marked carrier.

11. A method of generating a die location check (DLC) file for determining true positions of a plurality of semiconductor devices for an electronic module in a reconstructed panel, comprising:
conducting a post-bonding inspection for inspecting the plurality of semiconductor devices bonded on a marked carrier before forming the reconstructed panel;
forming a molding layer for encapsulating the plurality of semiconductor devices mounted on the marked carrier for forming the reconstructed panel; and
scanning the plurality of semiconductor devices in the reconstructed panel for detecting true positions of the semiconductor devices in the reconstructed panel.

12. The method of claim 11, wherein
the plurality of semiconductor devices comprise a semiconductor die, and
a true position of the semiconductor die is determined by a first die reference point and a second die reference point on a die active surface of the semiconductor die.

13. The method of claim 12, wherein the first die reference point and the second die reference point are determined by
shifting a first die offset and a second die offset from a die center of the semiconductor die respectively, or
shifting a first die reference point offset and a second die reference point offset from a first auxiliary reference point and a second auxiliary reference point respectively.

14. The method of claim 13, wherein the electronic module comprise a multiple chip module (MCM) which has at least two semiconductor dies, and scanning the plurality of semiconductor devices comprise scanning a selected semiconductor die only for the MCM.

15. The method of claim 13, wherein the electronic module comprises a multiple chip module (MCM) which has at least two semiconductor dies, and scanning the plurality of semiconductor devices comprise scanning all semiconductor dies of the MCM.

16. A panel-level semiconductor packaging method for making a plurality of electronic modules, comprising:
providing a marked carrier;
aligning and bonding a plurality of semiconductor devices onto the marked carrier;
forming a molding layer for forming a reconstructed panel;
releasing the reconstructed panel from the marked carrier and then transferring the reconstructed panel to a carrier plate;
forming a circuit layer on the plurality of semiconductor devices molded in the reconstructed panel by
generating a die location check (DLC) file which comprises true positions of the plurality of semiconductor devices in the reconstructed panel;
retrieving a green circuit file having green positions for the plurality of semiconductor devices;
transforming the green circuit file to an adapted circuit file using the DLC file, wherein the green positions are aligned to the true positions for the plurality of semiconductor devices; and
forming the circuit layer on the plurality of semiconductor devices at the true positions according to the adapted circuit file;
forming an external connection layer on circuit layer; and
singulating the reconstructed panel and the external connection layer into each of the plurality of electronic modules.

17. The method of claim 16, wherein the semiconductor devices comprise a plurality of semiconductor dies and a plurality of passive packages and further comprising aligning and bonding the plurality of semiconductor dies of the plurality of electronic modules onto the marked carrier.

18. The method of claim 17, wherein the plurality of passive packages is made by:
providing a substrate;
mounting a plurality of passive components onto the substrate;
forming an encapsulation layer for forming a molded structure;
exposing electrical connections of the passive components in the molded structure;
releasing the molded structure from the substrate; and
separating the molded structure into the plurality of passive packages.

19. The method of claim 17, wherein aligning and bonding the plurality of semiconductor dies onto the marked carrier further comprise:
for each semiconductor die of the plurality of semiconductor dies, determining a first die reference point and a second die reference point;
determining a first region reference point and a second region reference point on the marked carrier; and
aligning the first die reference point and the second die reference point to the first region reference point and the second region reference point respectively for aligning the semiconductor die to its bonding region on the marked carrier.

20. The method of claim 19, wherein
the first die reference point and the second die reference point are matched respectively from a first CAD die reference point and a second CAD die reference point of a CAD die file for the semiconductor die; and
the first region reference point and the second region reference point are matched respectively from a first CAD region reference point and a second CAD region reference point of a CAD bonding region on the marked carrier.
